(19) United States
(12) Patent Application Publication
(10) Pub. No.: US 2022/0336761 A1
(43) Pub. Date: Oct. 20, 2022

(54) RESIN FILM, ELECTRONIC DEVICE, METHOD OF MANUFACTURING RESIN FILM, AND METHOD OF MANUFACTURING ELECTRONIC DEVICE

(71) Applicant: Toray Industries, Inc., Tokyo (JP)

(72) Inventors: Tomoki Ashibe, Otsu-shi, Shiga (JP); Daichi Miyazaki, Otsu-shi, Shiga (JP); Takuya Miyauchi, Otsu-shi, Shiga (JP)

(73) Assignee: Toray Industries, Inc., Tokyo (JP)

(21) Appl. No.: 17/639,981

(22) PCT Filed: Sep. 14, 2020
(86) PCT No.: PCT/JP2020/034784

§ 371 Date: Mar. 3, 2022

(30) Foreign Application Priority Data
Sep. 24, 2019 (JP) 2019-173521
Sep. 24, 2019 (JP) 2019-173522

(51) Int. Cl. H01L 51/00; C09D 179/08; C09D 5/24; H01L 51/56

(52) U.S. Cl. CPC H01L 51/0097; C09D 179/08; C09D 5/24; H01L 51/56

(57) ABSTRACT

A resin film according to one aspect of the present invention contains polyimide, and satisfies the condition “the electric charge change in film after irradiation with a light having a wavelength of 470 nm and an intensity of 4.0 μW/cm² for 30 minutes relative to before irradiation with the light is 1.0×10¹⁶ cm⁻³ or less.” Such a resin film can be used as a substrate for a semiconductor element to form an electronic device including the resin film, and a semiconductor element formed on the resin film.

### CROSS REFERENCE TO RELATED APPLICATIONS

This is the U.S. National Phase application of PCT/JP2020/034784, filed Sep. 14, 2020, which claims priority to Japanese Patent Application No. 2019-173522, filed Sep. 24, 2019 and Japanese Patent Application No. 2019-173521, filed Sep. 24, 2019, the disclosures of each of these applications being incorporated herein by reference in their entireties for all purposes.

### FIELD OF THE INVENTION

The present invention relates to resin films, electronic devices, methods of manufacturing resin films, and methods of manufacturing electronic devices.

### BACKGROUND OF THE INVENTION

Polyimide is used as a material for various electronic devices such as semiconductors and displays due to its excellent electrical insulating properties, heat resistance, and mechanical properties. In recent years, development of flexible electronic devices has been ongoing that uses a polyimide film in the substrate (in particular, flexible substrate) of image display devices and touch panels, such as organic EL displays, electronic papers, and color filters.

When polyimide is used as a material for a substrate, a polyimide film is formed by applying a polyamic acid solution (hereinafter, referred to as “varnish” as appropriate) to a support and firing the coating film. Polyimide for substrates is required to have excellent mechanical properties, low coefficient of linear thermal expansion (hereinafter, referred to as “CTE” as appropriate) to reduce warping of substrates during manufacture, high heat resistance that enables the polyimide to withstand the temperature at which electronic devices are manufactured, and the like.

For example, Patent Literature 1 discloses an example in which a flexible organic EL display is manufactured by preparing a polyimide film that is excellent in mechanical strength, and forming a thin-film transistor (TFT) that is a semiconductor element, and an organic EL element on the film. In addition, Patent Literature 2 discloses an example in which a flexible organic EL display is manufactured by preparing a polyimide film that is excellent in mechanical strength and heat resistance and has low coefficient of linear thermal expansion, and forming a TFT and an organic EL element on the film.

### Patent Literature

Patent Literature 1: WO2017/099183
Patent Literature 2: WO2019/049517

### SUMMARY OF THE INVENTION

However, the polyimide films disclosed in Patent Literatures 1 and 2, when used as substrates of TFTs in organic EL displays, may cause a threshold voltage shift in the TFTs during a long-term operation by the organic EL displays. This has problematically resulted in such cases that lead to decrease in the reliability of organic EL displays, for example, changes in the emission luminance of organic EL elements over time, and unintentional persistence of faint light emission from organic EL elements even when the power is turned off.

The first object of the present invention, which has been made in view of the problems described above, is to provide a resin film that can be used as a substrate for a semiconductor element such as TFT to prevent changes in the properties of the semiconductor element during a long-term operation and contribute to improved reliability of the electronic device. In addition, the second object of the present invention is to provide an electronic device that uses such a resin film as a substrate for a semiconductor element, allowing for improvement of its reliability.

To solve the problems and achieve the objects described above, the resin film according to embodiments of the present invention is characterized in that it is a resin film comprising polyimide; and that the electric charge change in film, which is the amount of change in the electric charge in the resin film, after irradiation with a light having a wavelength of 470 nm and an intensity of 4.0 μW/cm² for 30 minutes, relative to before irradiation with the light, is 1.0×10¹⁶ cm⁻³ or less.

In the invention described above, the resin film according to an embodiment of the present invention is characterized in that the 0.05% weight loss temperature is 490° C. or higher.

In the aspect described above, the resin film according to an embodiment of the present invention is characterized in that the light transmittance at a wavelength of 470 nm when the thickness of the resin film is set to 10 μm is 60% or more.

In the aspect described above, the resin film according to an embodiment of the present invention is characterized in that 50 mol % or more of the 100 mol % of tetracarboxylic acid residues contained in the polyimide is composed of at least one selected from a pyromellitic acid residue and a biphenyltetracarboxylic acid residue; and that 50 mol % or more of the diamine residues contained in the 100 mol % of polyimide is composed of p-phenylenediamine residue.

In the aspect described above, the resin film according to an embodiment of the present invention is characterized in that the value obtained by dividing the number of moles of the tetracarboxylic acid residues contained in the polyimide by the number of moles of the diamine residues contained in the polyimide is from 1.001 to 1.100.

In the aspect described above, the resin film according to an embodiment of the present invention is characterized in that the polyimide comprises at least one of the structure represented by Chemical Formula (1) and the structure represented by Chemical Formula (2):

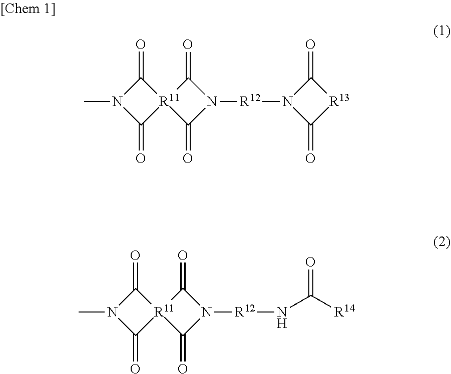

wherein, in Chemical Formula (1), R¹¹ represents a tetravalent tetracarboxylic acid residue having two or more carbon atoms;

R¹² represents a divalent diamine residue having two or more carbon atoms;

and

R¹³ represents a divalent dicarboxylic acid residue having two or more carbon atoms;

and wherein, in Chemical Formula (2), R¹¹ represents a tetravalent tetracarboxylic acid residue having two or more carbon atoms;

R¹² represents a divalent diamine residue having two or more carbon atoms; and

R¹⁴ represents a monovalent carboxylic acid residue having one or more carbon atoms.

The electronic device according to embodiments of the present invention is characterized in that it comprises: a resin film according to any one of the aspects described above; and a semiconductor element formed on the resin film.

In the aspect described above, the electronic device according to an embodiment of the present invention is characterized in that the semiconductor element is a thin-film transistor.

In the aspect described above, the electronic device according to an embodiment of the present invention is characterized in that it further comprises an image display element.

The method of producing a resin film according to embodiments of the present invention is characterized in that it is a method of producing a resin film according to any one of the aspects described above, comprising: an application step for applying a resin composition comprising a polyimide precursor and a solvent to a support; and a heating step for heating the coating film obtained by the application step to obtain a resin film.

In the aspect described above, the method of manufacturing the resin film according to an embodiment of the present invention is characterized in that the heating temperature for the coating film in the heating step is from 420° C. to 490° C.

In the invention described above, the method of manufacturing the resin film according to an embodiment of the present invention is characterized in that the polyimide precursor has the structure represented by Chemical Formula (3):

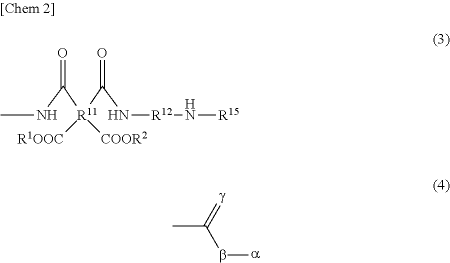

wherein, in Chemical Formula (3), R¹¹ represents a tetravalent tetracarboxylic acid residue having two or more carbon atoms;

R¹² represents a divalent diamine residue having two or more carbon atoms;

R¹⁵ represents the structure represented by Chemical Formula (4); and

R¹ and R² each independently represent a hydrogen atom, a hydrocarbon group having 1 to 10 carbon atoms, an alkylsilyl group having 1 to 10 carbon atoms, an alkali metal ion, an ammonium ion, an imidazolium ion, or a pyridinium ion;

and wherein, in Chemical Formula (4), α represents a monovalent hydrocarbon group having two or more carbon atoms; and

β and γ each independently represent an oxygen atom or a sulfur atom.

In the invention described above, the method of manufacturing the resin film according to an embodiment of the present invention is characterized in that the polyimide precursor has the structure represented by Chemical Formula (5):

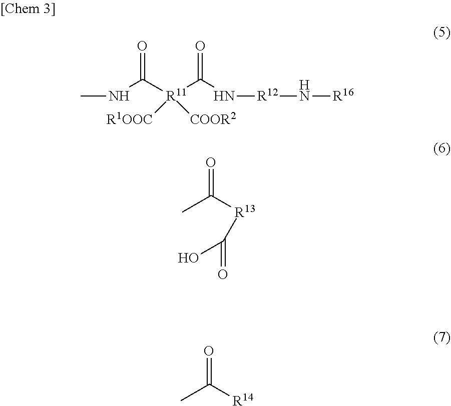

wherein, in Chemical Formula (5), R¹¹ represents a tetravalent tetracarboxylic acid residue having two or more carbon atoms;

R¹² represents a divalent diamine residue having two or more carbon atoms;

R¹⁶ represents the structure represented by Chemical Formula (6) or the structure represented by Chemical Formula (7);

and wherein, in Chemical Formula (6), R¹³ represents a divalent dicarboxylic acid residue having two or more carbon atoms;

and wherein, in Chemical Formula (7), R¹⁴ represents a monovalent monocarboxylic acid residue having one or more carbon atoms.

In the invention described above, the method of manufacturing the resin film according to an embodiment of the present invention is characterized in that the resin composition comprises at least one of a compound having the structure represented by Chemical Formula (8) and a compound having the structure represented by Chemical Formula (9) in an amount ranging from 0.05 parts by mass to 5.0 parts by mass based on 100 parts by mass of the polyimide precursor;

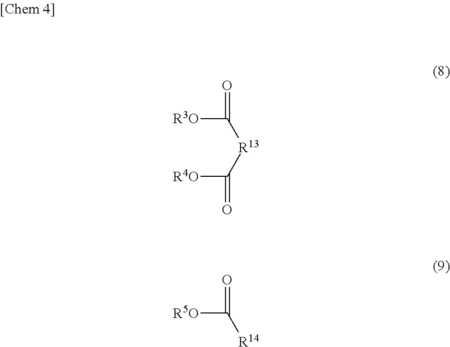

wherein, in Chemical Formula (8), R¹³ represents a divalent dicarboxylic acid residue having two or more carbon atoms; and

R³ and R⁴ each independently represent a hydrogen atom, a hydrocarbon group having 1 to 10 carbon atoms, an alkylsilyl group having 1 to 10 carbon atoms, an alkali metal ion, an ammonium ion, an imidazolium ion, or a pyridinium ion;

and wherein, in Chemical Formula (9), R¹⁴ represents a monovalent monocarboxylic acid residue having one or more carbon atoms; and

R⁵ represents a hydrogen atom, a hydrocarbon group having 1 to 10 carbon atoms, an alkylsilyl group having 1 to 10 carbon atoms, an alkali metal ion, an ammonium ion, an imidazolium ion, or a pyridinium ion.

The method of manufacturing an electronic device according to embodiments of the present invention is characterized in that it comprises: a film production step for producing a resin film on a support by the method of producing a resin film according to any one of the inventions described above; an element formation step for forming a semiconductor element on the resin film; and a separation step for separating the resin film from the support.

In the invention described above, the method of manufacturing an electronic device according to an embodiment of the present invention is characterized in that the semiconductor element is a thin-film transistor.

The resin film according to embodiments of the present invention can be used as a substrate for a semiconductor element to prevent changes in the properties of the semiconductor element during a long-term operation and contribute to improved reliability of the electronic device comprising the semiconductor element, as an effect achieved thereby. The electronic device according to embodiments of the present invention comprises such a resin film as a substrate for a semiconductor element, allowing for improvement of its reliability during a long-term operation, as an effect achieved thereby.

### BRIEF DESCRIPTION OF DRAWINGS

The FIGURE is a schematic cross-sectional view showing an exemplary electronic device according to embodiments of the present invention.

### DETAILED DESCRIPTION OF EMBODIMENTS OF THE INVENTION

Embodiments of the present invention will now be described in detail. However, the present invention is not limited to the embodiments described below, and various modifications can be made according to the purposes and applications for carrying out the invention.

### (Resin Film)

A resin film according to embodiments of the present invention (hereinafter, abbreviated as “resin film of the present invention” as appropriate) is a resin film comprising polyimide, and satisfies the conditions on the electric charge change in film as shown below. Specifically, the resin film of the present invention satisfies the condition “the electric charge change in film after irradiation with a light having a wavelength of 470 nm and an intensity of 4.0 μW/cm² for 30 minutes is 1.0×10¹⁶ cm⁻³ or less.” As used herein, the term “electric charge change in film” refers to the amount of change in the electric charge in the resin film after irradiation with the light described above for 30 minutes relative to before irradiation with the light. Such electric charge change in film can be calculated, for example, by subtracting the amount of the electric charge in a resin film before irradiation with a light from the amount of the electric charge accumulated in the resin film after irradiation with the light for 30 minutes.

The resin film of the present invention having the characteristics described above can be used as a substrate (e.g., flexible substrate) of a semiconductor element to prevent changes in the properties of the semiconductor element during a long-term operation. The resin film of the present invention can also be provided in an electronic device as a substrate for a semiconductor element to improve the reliability of the electronic device. In particular, when the semiconductor element is a TFT, and the electronic device is an organic EL display, the resin film of the present invention can prevent threshold voltage shift of the TFT, thereby improving the reliability of the organic EL display.

The reason why the resin film according to embodiments of the present invention exert the described above is presumed as follows. That is, a semiconductor element formed on a substrate, when electric charge exists in the substrate, is affected by the electric field caused by the electric charge, which changes the carrier density in the semiconductor element and changes the electrical characteristics of the semiconductor element. For example, when a top gate TFT is formed on a substrate, and an electric charge exists in the substrate, the substrate serves as a back gate to change the threshold voltage of the TFT. When the amount of the electric charge in the substrate changes during operation of the semiconductor element, the electrical characteristics of the semiconductor element will change over time, and thus the reliability of the electronic device comprising the semiconductor element will be impaired. Specifically, when a polyimide film is used as a substrate, the amount of the electric charge in the polyimide film (hereinafter referred to as “electric charge in film” as appropriate) is presumed to change as a semiconductor element on the polyimide film operates.

The mechanism by which the electric charge in film is changed in the use of the polyimide film is considered as follows. Specifically, most polyimides with high heat resistance have the highest occupied molecular orbital (HOMO) that is unevenly distributed in the diamine moiety, and have the lowest unoccupied molecular orbital (LUMO) that is unevenly distributed in the acid dianhydride. Thus, the electronic transition from HOMO to LUMO in the polyimide film means charge transfer transition resulted from the charge transfer from the diamine moiety to the acid dianhydride moiety. When charge transfer transition occurs, an electric charge is generated in the polyimide film as the result of the charge transfer transition, which generated electric charge, in turn, is trapped in the polyimide film. This is considered to result in the change in the electric charge in film.

The substrate for the semiconductor element is subjected to external stresses, such as light (e.g., environmental light and light emitted from display device), heat (e.g., Joule heat), and electric field during operation of the semiconductor element on the substrate. Therefore, it is considered that, when polyimide is used as a material for the substrate, such external stresses during operation of the semiconductor element causes charge transfer transition in the polyimide, resulting in a change in the electric charge in film of the substrate. In particular, charge transfer transition of polyimide is known to be caused by photoexcitation in the visible range including light having a wavelength of 470 nm. Thus, it is considered that the impact of light is the most significant among the external stresses described above. When the electronic device is an organic EL display, light having a wavelength of 470 nm is included in the blue light emitted from the organic EL display (specifically, an organic EL element). Thus, it is considered that organic EL display is notably prone to charge transfer transition in polyimide, so that the electric charge in film of the substrate is likely to be changed during operation of the organic EL display.

The resin film according to embodiments of the present invention is a resin film comprising polyimide as described above, which satisfies the condition “the electric charge change in film after irradiation with a light having a wavelength of 470 nm and an intensity of 4.0 μW/cm² for 30 minutes is 1.0×10¹⁶ cm⁻³ or less.” That is, the resin film of the present invention is a resin film that is less likely to cause electric charge change in film due to the external stress described above even when it contains polyimide. Thus, when the resin film of the present invention is used as a substrate for a semiconductor element, the electric charge change in film during operation of the semiconductor element can be reduced, resulting in reduced change in the amount of carriers in the semiconductor element. Therefore, changes in the properties of the semiconductor element can be prevented to provide an electronic device with excellent reliability.

### (Electric Charge Change in Film)

The electric charge change in film in the present invention is a value determined by the following method. The method of determining the electric charge change in film in the present invention comprises first preparing a laminate as a measurement sample, in which a silicon wafer that is a semiconductor layer, a thermal oxide film, and a resin film comprising polyimide (a resin film to be analyzed) are laminated in this order. Then, the measurement sample is placed in a dark chamber of an apparatus for measuring the capacitance-voltage characteristics (CV characteristics). The measurement sample is inserted between a pair of electrodes included in the measurement apparatus to form a capacitor structure comprising the measurement sample. Then, by applying a DC bias voltage and an AC voltage to the capacitor structure, the capacitance of the capacitor structure in a state with accumulated electric charge due to application of voltage and the applied voltage are measured. Based on the obtained capacitance and applied voltage measurements, the CV characteristics of the capacitor structure are measured. Thereafter, based on the CV characteristics measurement results, the flat band voltage V_{FB}1 of the capacitor structure is determined.

Next, the resin film of the measurement sample constituting the capacitor structure was irradiated with light from the light source of the measurement apparatus to cause an electric charge in the resin film due to photoexcitation. At this time, the light source-side electrode of the pair of electrodes sandwiching the measurement sample in the capacitor structure is detached from the resin film of the measurement sample, and again contacted with the measurement sample after light irradiation to the resin film. In this embodiment, the light wavelength from the light source is 470 nm; and the intensity of the light is 4.0 μW/cm². The irradiation time of the light is 30 minutes. Then, by applying a DC bias voltage and an AC voltage as described above to the photoirradiated capacitor structure, the capacitance of the photoirradiated capacitor structure in a state with accumulated electric charges due to application of voltage and photoexcitation, and the applied voltage are measured. Based on the obtained capacitance and applied voltage measurements, the CV characteristics of the photoirradiated capacitor structure are measured. Thereafter, based on the CV characteristics measurement results, the flat band voltage V_{FB}2 of the photoirradiated capacitor structure is determined.

Then, using flat band voltages V_{FB}1 and V_{FB}2 before and after light irradiation obtained as described above, the flat band voltage difference ΔV_{FB} is determined according to the following formula (F1). Thereafter, using the obtained flat band voltage difference ΔV_{FB} and capacitance in charge storage state C₁, the increase of electric charge due to photoexcitation per unit volume in the resin film, or the electric charge change in film of the resin film, Q[cm⁻³], is determined according to the following formula (F2).

ΔV_{FB}=|V_{FB}2−V_{FB}1| (F1)

Q=C₁×ΔV_{FB}/(qSt) (F2)

In the formula (F2), q is the elementary charge (1.6×10⁻¹⁹ [C]); S is the area of the light source-side electrode [cm²]; and t is the thickness of the resin film to be analyzed [cm].

The resin film of the measurement sample with the electric charge change in film Q obtained as described above being 1.0×10¹⁶ cm⁻³ or less is used as the resin film in the present invention. In the measurement of the CV characteristics of the capacitor structure, the light source-side electrode of the pair of electrodes is a mercury probe, a movable electrode that is in detachably contact with the resin film of the measurement sample.

### (Polyimide)

The resin film according to embodiments of the present invention contains polyimide. Preferably, the polyimide is a resin having a repeating unit represented by Chemical Formula (10).

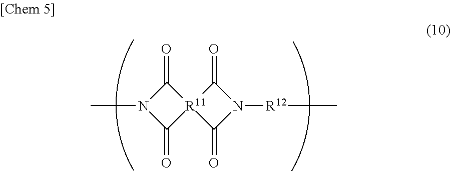

In Chemical Formula (10), R¹¹ represents a tetravalent tetracarboxylic acid residue having two or more carbon atoms. R¹² represents a divalent diamine residue having two or more carbon atoms. Preferably, in Chemical Formula (10) in the present invention, R¹¹ is a tetravalent hydrocarbon group having 2 to 80 carbon atoms. R¹¹ may also be a tetravalent organic group having 2 to 80 carbon atoms, the group containing hydrogen and carbon as essential components, and containing one or more atoms selected from boron, oxygen, sulfur, nitrogen, phosphorus, silicon, and halogen. The numbers of the boron, oxygen, sulfur, nitrogen, phosphorus, silicon, and halogen atoms contained in the organic group, each independently, are preferably in the range of 20 or less, and more preferably in the range of 10 or less.

The tetracarboxylic acid that provides R¹¹ is not particularly restricted, and a known tetracarboxylic acid can be used. Examples of the tetracarboxylic acid include pyromellitic acid, 3,3′,4,4′-biphenyltetracarboxylic acid, 2,3,3′,4′-biphenyltetracarboxylic acid, 2,2′,3,3′-biphenyltetracarboxylic acid, 3,3′,4,4′-benzophenonetetracarboxylic acid, 2,2-bis(3,4-dicarboxyphenyl)hexafluoropropane, bis(3,4-dicarboxyphenyl)sulfone, bis(3,4-dicarboxyphenyl)ether, cyclobutanetetracarboxylic acid, 1,2,3,4-cyclopentanetetracarboxylic acid, and 1,2,4,5-cyclohexane tetracarboxylic acid, as well as tetracarboxylic acids described in WO2017/099183.

These tetracarboxylic acids can be used as they are, or in a state of an acid anhydride, an activated ester, or an activated amide. In addition, these compounds may be used in combination of two or more of them as tetracarboxylic acids that provide R¹¹.

From the viewpoint of improving the heat resistance of the resin film of the present invention, 50 mol % or more of the 100 mol % of tetracarboxylic acid residue contained in the polyimide is preferably composed of an aromatic tetracarboxylic acid residue. Especially, 50 mol % or more of the tetracarboxylic acid residue is more preferably composed of at least one selected from a pyromellitic acid residue and a biphenyltetracarboxylic acid residue. Further, 80 mol % or more of the 100 mol % of tetracarboxylic acid residue is more preferably composed of at least one selected from a pyromellitic acid residue and a biphenyltetracarboxylic acid residue. Polyimides obtained from these tetracarboxylic acids can provide resin films having low CTE.

In addition, in order to improve the application properties to the support and the resistance to oxygen plasma and UV ozone treatment used in washing and the like, silicon-containing tetracarboxylic acids, such as dimethylsilane diphthalate and 1,3-bis(phthalic acid) tetramethyldisiloxane may be used as a tetracarboxylic acid that provides R¹¹. When the silicon-containing tetracarboxylic acid is used, the silicon-containing tetracarboxylic acid is preferably used in an amount of 1 mol % to 30 mol % relative to the total tetracarboxylic acids.

In the tetracarboxylic acids as exemplified above, some hydrogen contained in the tetracarboxylic acid residue may be substituted with hydrocarbon groups having 1 to 10 carbon atoms, such as methyl groups and ethyl groups, fluoroalkyl groups having 1 to 10 carbon atoms, such as trifluoromethyl groups, and groups such as F, Cl, Br, and I. Furthermore, when some hydrogen contained in the residue is substituted with acidic groups, such as OH, COOH, SO₃H, CONH₂, and SO₂NH₂, the solubility of the polyimide and the precursor thereof into an aqueous alkali solution is increased, and thus this substitution is preferable in the case of use as a photosensitive resin composition described below.

In Chemical Formula (10), R¹² is preferably a divalent hydrocarbon group having 2 to 80 carbon atoms. R¹² may also be a divalent organic group having 2 to 80 carbon atoms, the group containing hydrogen and carbon as essential components, and containing one or more atoms selected from boron, oxygen, sulfur, nitrogen, phosphorus, silicon, and halogen. The numbers of the boron, oxygen, sulfur, nitrogen, phosphorus, silicon, and halogen atoms contained in R¹², each independently, are preferably in the range of 20 or less, and more preferably in the range of 10 or less.

The diamine that provides R¹² is not particularly restricted, and a known diamine can be used. Examples of the diamine include m-phenylenediamine, p-phenylenediamine, 4,4′-diaminobenzanilide, 3,4′-diaminodiphenyl ether, 4,4′-diaminodiphenyl ether, 2,2′-dimethyl-4,4′-diaminobiphenyl, 2,2′-di(trifluoromethyl)-4,4′-diaminobiphenyl, bis(4-aminophenoxyphenyl)sulfone, 1,4-bis(4-aminophenoxy)benzene, 1,3-bis(3-aminophenoxy)benzene, 1,3-bis(4-aminophenoxy)benzene, bis(3-amino-4-hydroxyphenyl)hexafluoropropane, ethylenediamine, propylenediamine, butanediamine, 1,3-bis(3-aminopropyl)tetramethyldisiloxane, cyclohexanediamine, and 4,4′-methylenebis(cyclohexylamine), as well as diamines described in WO2017/099183.

These diamines can be used as they are or as a corresponding trimethylsilylated diamine. In addition, these compounds may be used in combination of two or more of them as diamines that provide R¹².

From the viewpoint of improving the heat resistance of the resin film of the present invention, 50 mol % or more of the 100 mol % of diamine residue contained in the polyimide is preferably composed of an aromatic diamine residue. Especially, 50 mol % or more of the diamine residue is more preferably composed of a p-phenylenediamine residue. Further, 80 mol % or more of the 100 mol % of diamine residue is more preferably composed of a p-phenylenediamine residue. Polyimides obtained by using p-phenylenediamine can provide resin films having low CTE.

It is particularly preferable in the polyimide contained in the resin film of the present invention that 50 mol % or more of the 100 mol % of tetracarboxylic acid residues contained in the polyimide is composed of at least one selected from a pyromellitic acid residue and a biphenyltetracarboxylic acid residue; and that 50 mol % or more of the diamine residues contained in the 100 mol % of polyimide is composed of a p-phenylenediamine residue. Polyimides having such a structure can provide resin films having a suitably low CTE.

The value (division value Ka) obtained by dividing the number of moles of the tetracarboxylic acid residues contained in the polyimide by the number of moles of the diamine residues contained in the polyimide is preferably 1.001 or more, and more preferably 1.005 or more. The division value Ka is preferably 1.100 or less, and more preferably 1.060 or less. When the division value Ka is 1.001 or more, the terminal structure of the polyimide is likely to be an acid anhydride, which can reduce the amount of amine terminals that often trap electric charge in the polyimide. This results in reduction in the electric charge change in film during light irradiation in the resin film comprising the polyimide. When the division value Ka is 1.100 or less, the molecular weight of the polyimide increases, which results in reduction in the amount of the terminal structures of the polyimide present in the resin film. This results in reduction in the electric charge change in film during light irradiation in the resin film comprising the polyimide.

In addition, in order to improve the application properties to a support and the resistance to oxygen plasma and UV ozone treatment used in washing and the like, silicon-containing diamines, such as 1,3-bis(3-aminopropyl)tetramethyldisiloxane and 1,3-bis(4-anilino)tetramethyldisiloxane, may be used as diamine that provides R¹². When the silicon-containing diamine compound is used, the silicon-containing diamine compound is preferably used in an amount of 1 mol % to 30 mol % relative to the total diamine compounds.

In the diamine compound as exemplified above, some hydrogen contained in the diamine compound may be substituted with hydrocarbon groups having 1 to 10 carbon atoms, such as methyl groups and ethyl groups, fluoroalkyl groups having 1 to 10 carbon atoms, such as trifluoromethyl groups, and groups such as F, Cl, Br, and I. Furthermore, when some hydrogen contained in the diamine compound is substituted with acidic groups, such as OH, COOH, SO₃H, CONH₂, and SO₂NH₂, the solubility of the polyimide and the precursor thereof into an aqueous alkali solution is increased, and thus this substitution is preferable in the case of use as a photosensitive resin composition described below.

The polyimide contained in the resin film of the present invention may have terminals that are blocked by terminal blocking agents. The polyimide, when having blocked terminals, preferably comprises at least one of the structure represented by Chemical Formula (1) and the structure represented by Chemical Formula (2).

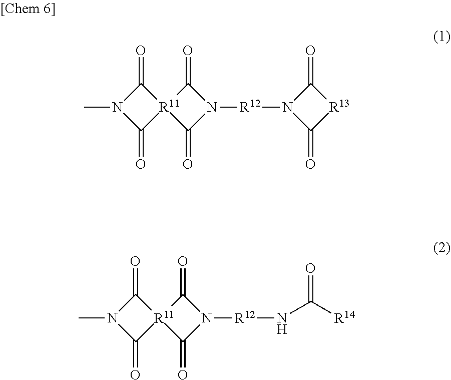

In Chemical Formula (1), R¹¹ and R¹² each are the same as R¹¹ and R¹² in Chemical Formula (10) as described above. R¹³ represents a divalent dicarboxylic acid residue having two or more carbon atoms. In Chemical Formula (2), R¹¹ represents a tetravalent tetracarboxylic acid residue having two or more carbon atoms. R¹² represents a divalent diamine residue having two or more carbon atoms. R¹⁴ represents a monovalent monocarboxylic acid residue having one or more carbon atoms.

In Chemical Formula (1), R¹³ is preferably a divalent hydrocarbon group having 2 to 80 carbon atoms. R¹³ may also be a divalent organic group having 2 to 80 carbon atoms, the group containing hydrogen and carbon as essential components, and containing one or more atoms selected from boron, oxygen, sulfur, nitrogen, phosphorus, silicon, and halogen. The numbers of the boron, oxygen, sulfur, nitrogen, phosphorus, silicon, and halogen atoms contained in R¹³, each independently, are preferably in the range of 20 or less, and more preferably in the range of 10 or less.

The dicarboxylic acid that provides R¹³ is not particularly restricted, and is preferably an aromatic dicarboxylic acid from the viewpoint of improving the heat resistance of the resin film. Examples of the aromatic dicarboxylic acid include phthalic acid, 3,4-biphenyldicarboxylic acid, 2,3-biphenyldicarboxylic acid, and 2,3-naphthalenedicarboxylic acid.

In Chemical Formula (2), R¹⁴ is preferably a monovalent hydrocarbon group having 1 to 80 carbon atoms. R¹⁴ may also be a monovalent organic group having 1 to 80 carbon atoms, the group containing hydrogen and carbon as essential components, and containing one or more atoms selected from boron, oxygen, sulfur, nitrogen, phosphorus, silicon, and halogen. The numbers of the boron, oxygen, sulfur, nitrogen, phosphorus, silicon, and halogen atoms contained in R¹⁴, each independently, are preferably in the range of 20 or less, and more preferably in the range of 10 or less.

The monocarboxylic acid that provides R¹⁴ is not particularly restricted, and is preferably an aromatic monocarboxylic acid from the viewpoint of improving the heat resistance of the resin film. Examples of the aromatic monocarboxylic acid include benzoic acid, 2-biphenylcarboxylic acid, 3-biphenylcarboxylic acid, 4-biphenylcarboxylic acid, 1-naphthalenecarboxylic acid, and 2-naphthalenecarboxylic acid.

The structure represented by Chemical Formula (1) is a structure in which the amine terminal of the polyimide is blocked by a dicarboxylic acid compound. The structure represented by Chemical Formula (2) is a structure in which the amine terminal of the polyimide is blocked by a monocarboxylic acid compound. Thus, when the polyimide has such a structure, there will be fewer amine terminals of the polyimide present in the resin film. This results in reduction in the electric charge change in film during light irradiation in the resin film comprising the polyimide.

Preferably, the resin having the structure represented by Chemical Formula (1) (resin of Chemical Formula (1)) satisfies the following conditions. Specifically, the value (division value Ka) obtained by dividing the number of moles of the tetracarboxylic acid residues contained in the resin of Chemical Formula (1) by the number of moles of the diamine residues contained in the resin is preferably 1.001 or more, and more preferably 1.005 or more. The division value Ka is preferably 1.100 or less, and more preferably 1.060 or less. When the division value Ka is 1.001 or more, the terminal structure of the resin of Chemical Formula (1) is likely to be an acid anhydride, which can reduce the amount of amine terminals that often trap electric charge in the resin. This results in reduction in the electric charge change in film during light irradiation in the resin film comprising the polyimide. When the division value Ka is 1.100 or less, the molecular weight of the polyimide increases, which results in reduction in the amount of the terminal structures of the polyimide present in the resin film. This results in reduction in the electric charge change in film during light irradiation in the resin film comprising the polyimide.

Similarly, the resin having the structure represented by Chemical Formula (2) (resin of Chemical Formula (2)) preferably satisfies the following conditions. Specifically, the division value Ka in the resin of Chemical Formula (2) is preferably 1.001 or more, and more preferably 1.005 or more. The division value Ka is preferably 1.100 or less, and more preferably 1.060 or less. When the division value Ka is 1.001 or more, the terminal structure of the resin of Chemical Formula (2) is likely to be an acid anhydride, which can reduce the amount of amine terminals that often trap electric charge in the resin. This results in reduction in the electric charge change in film during light irradiation in the resin film comprising the polyimide. When the division value Ka is 1.100 or less, the molecular weight of the polyimide increases, which results in reduction in the amount of the terminal structures of the polyimide present in the resin film. This results in reduction in the electric charge change in film during light irradiation in the resin film comprising the polyimide.

### (Method for Producing Resin Composition)

The resin film according to embodiments of the present invention can be obtained by applying a resin composition comprising polyimide or a precursor thereof and a solvent to a support, and then firing the resin composition. The polyimide precursor refers to a resin that can be converted into the polyimide by heat treatment, chemical treatment, or other treatment. A polyimide precursor that can be preferably used in the present invention is polyamic acid. Preferably, the polyamic acid is a resin having a repeating unit represented by Chemical Formula (11).

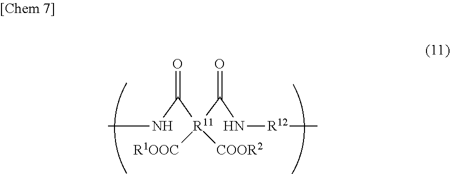

In Chemical Formula (11), R¹ and R² represents a hydrogen atom, an alkali metal ion, an ammonium ion, an imidazolium ion, a hydrocarbon group having 1 to 10 carbon atoms, or an alkylsilyl group having 1 to 10 carbon atoms. R¹¹ and R¹² each are the same as R¹¹ and R¹² in Chemical Formula (10) as described above. Specific examples of R¹¹ in Chemical Formula (11) include the structure described as a specific example of R¹¹ in Chemical Formula (10) as described above. Specific examples of R¹² in Chemical Formula (11) include the structure described as a specific example of R¹² in Chemical Formula (10) as described above.

The polyimide precursor in the present invention may have terminals that are blocked by terminal blocking agents. By blocking terminals of the polyimide precursor, the molecular weight of the polyimide precursor can be adjusted to a preferred range.

When the terminal monomer of the polyimide precursor is a diamine compound, a dicarboxylic anhydride, a monocarboxylic acid, a monocarboxyl chloride compound, a monocarboxylic acid activated ester compound, a dialkyl dicarbonate ester, or the like can be used as the terminal blocking agent to block the amino group of the diamine compound. When the terminal monomer of the polyimide precursor is an acid dianhydride, monoamine, monoalcohol, or other like can be used as the terminal blocking agent to block the acid anhydride group of the acid dianhydride.

When the polyimide precursor has a blocked amine terminal, the polyimide precursor preferably has the structure represented by Chemical Formula (3).

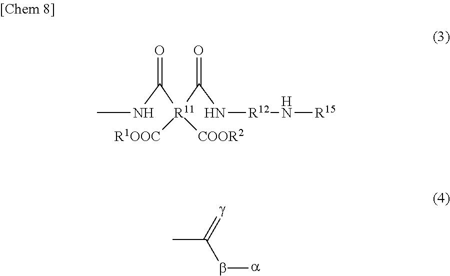

In Chemical Formula (3), R¹¹ and R¹² each are the same as R¹¹ and R¹² in Chemical Formula (10) as described above. R¹⁵ represents the terminal structure of the resin, and specifically represents the structure represented by Chemical Formula (4). R¹ and R², each independently, represents a hydrogen atom, a hydrocarbon group having 1 to 10 carbon atoms, an alkylsilyl group having 1 to 10 carbon atoms, an alkali metal ion, an ammonium ion, an imidazolium ion, or a pyridinium ion.

In Chemical Formula (4), α represents a monovalent hydrocarbon group having two or more carbon atoms. Preferably, α is a monovalent hydrocarbon group having 2 to 10 carbon atoms. More preferably, α is an aliphatic hydrocarbon group. The aliphatic hydrocarbon group may be any of linear, branched-chain, and cyclic aliphatic hydrocarbon groups. In Chemical Formula (4), β and γ, each independently, represents an oxygen atom or a sulfur atom. Preferably, β and γ each are an oxygen atom.

Examples of such a hydrocarbon group include linear hydrocarbon groups such as an ethyl group, a n-propyl group, a n-butyl group, a n-pentyl group, a n-hexyl group, a n-heptyl group, a n-octyl group, a n-nonyl group, and a n-decyl group; branched-chain hydrocarbon groups such as an isopropyl group, an isobutyl group, a sec-butyl group, a tert-butyl group, an isopentyl group, a sec-pentyl group, a tert-pentyl group, an isohexyl group, and a sec-hexyl group; and cyclic hydrocarbon groups such as a cyclopropyl group, a cyclobutyl group, a cyclopentyl group, a cyclohexyl group, a cycloheptyl group, a cyclooctyl group, a norbornyl group, and an adamantyl group.

Among these hydrocarbon groups, a monovalent branched-chain hydrocarbon group and a cyclic hydrocarbon group having 2 to 10 carbon atoms are preferable, an isopropyl group, a cyclohexyl group, a tert-butyl group, and a tert-pentyl group are more preferable, and a tert-butyl group is the most preferable.

When the resin having the structure represented by Chemical Formula (3) is heated, R¹⁵ is thermally decomposed to generate an amino group at the terminal of the resin. The amino group generated at the terminal can react with another resin having a tetracarboxylic acid at the terminal. Thus, a resin obtained by heating a resin having the structure represented by Chemical Formula (3) will have higher molecular weight and fewer terminal structures. A resin film comprising such a resin (specifically, polyimide) can reduce the electric charge change in film during light irradiation.

Preferably, the resin having the structure represented by Chemical Formula (3) satisfies the following conditions. Specifically, the value (division value Kb) obtained by dividing the number of moles of the tetracarboxylic acid residues contained in the resin by the number of moles of the diamine residues contained in the resin is preferably 1.001 or more, and more preferably 1.005 or more. The division value Kb is preferably 1.100 or less, and more preferably 1.060 or less. When the division value Kb is 1.001 or more, almost all of the amino groups generated through the thermal decomposition of R¹⁵ during heating of the resin react with acid anhydride groups present in the terminals of other resins. Thus, the resin (specifically, polyimide) obtained by heating has an extremely high molecular weight and particularly few amine terminals. This suitably results in reduction in the electric charge change in film during light irradiation in the resin film comprising the polyimide. When the division value Kb is 1.100 or less, the molecular weight of the resin (specifically, polyimide) obtained by heating increases, which results in reduction in the amount of the terminal structures of the polyimide present in the resin film. This results in reduction in the electric charge change in film during light irradiation in the resin film comprising the polyimide.

When the polyimide precursor has a blocked amine terminal, the polyimide precursor preferably has the structure represented by Chemical Formula (5).

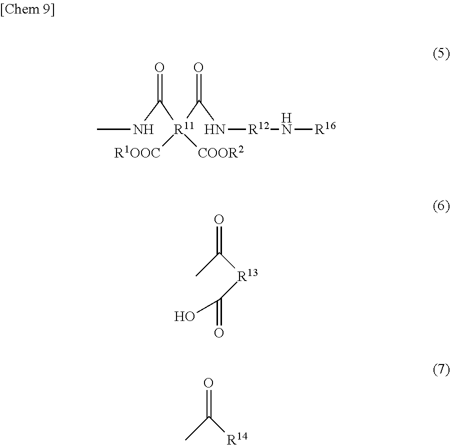

In Chemical Formula (5), R¹¹ and R¹² each are the same as R¹¹ and R¹² in Chemical Formula (10) as described above. R¹⁶ represents the terminal structure of the resin, and specifically represents the structure represented by Chemical Formula (6) or the structure represented by Chemical Formula (7). In Chemical Formula (6), R¹³ represents a divalent dicarboxylic acid residue having two or more carbon atoms. In Chemical Formula (7), R¹⁴ represents a monovalent monocarboxylic acid residue having one or more carbon atoms.

When R¹⁶ in Chemical Formula (5) is the structure represented by Chemical Formula (6), heating a resin having the structure represented by Chemical Formula (5) results in obtaining a resin having the structure represented by Chemical Formula (1) described above. When R¹⁶ in Chemical Formula (5) is the structure represented by Chemical Formula (7), heating a resin having the structure represented by Chemical Formula (5) results in obtaining a resin having the structure represented by Chemical Formula (2) described above.

The solvent contained in the resin composition is not particularly restricted, and any solvent in which dissolve polyimide and a precursor thereof can be used. Examples of such a solvent include aprotic polar solvents such as N-methyl-2-pyrrolidone, γ-butyrolactone, N,N-dimethylformamide, N,N-dimethylacetamide, 3-methoxy-N,N-dimethylpropionamido, 3-butoxy-N,N-dimethylpropionamido, N,N-dimethylisobutylamide, 1,3-dimethyl-2-imidazolidinone, N,N′-dimethylpropyleneurea, and dimethyl sulfoxide; ethers such as tetrahydrofuran, dioxane, propylene glycol monomethyl ether, propylene glycol monoethyl ether, diethylene glycol monomethyl ether, diethylene glycol monoethyl ether, diethylene glycol ethyl methyl ether, and diethylene glycol dimethyl ether; ketones such as acetone, methyl ethyl ketone, diisobutyl ketone, diacetone alcohol, and cyclohexanone; esters such as ethyl acetate, propylene glycol monomethyl ether acetate, ethyl lactate, 3-methyl-3-methoxybutyl acetate, ethylene glycol ethyl ether acetate, and 3-methoxybutyl acetate; aromatic hydrocarbons such as toluene and xylene; and solvents described in WO2017/099183. As the solvent, any of them can be used alone, or two or more of them can be used in combination.

Polyimide or a precursor thereof can be polymerized according to known methods. For example, in the case of producing polyamic acid as a polyimide precursor, tetracarboxylic acid, or the corresponding acid dianhydride, activated ester, activated amide, or the like used as the acid component, and diamine, or the corresponding trimethylsilylated diamine or the like used as the diamine component can be polymerized in a reaction solvent to obtain polyamic acid. In addition, the carboxy group in the polyamic acid may form a salt with an alkali metal ion, an ammonium ion, or an imidazolium ion, or esterified with a hydrocarbon group having 1 to 10 carbon atoms or an alkylsilyl group having 1 to 10 carbon atoms.

In the case of producing polyimide having blocked terminals or a precursor thereof, a monomer before polymerization, or polyimide or a precursor thereof during and after polymerization can be reacted with a terminal blocking agent to obtain the target polyimide or a precursor thereof. For example, a resin having the structure represented by Chemical Formula (3) or (5) described above can be produced using polyimide having blocked terminals or a precursor thereof according to the following two methods.

The first production method is a method of producing a resin having the structure represented by Chemical Formula (3) or (5) according to a two-step method as described below. Specifically, in the first step of the production method, a diamine compound and a terminal amino group blocking agent are reacted to produce a compound represented by Chemical Formula (41) or (51). In the present invention, the terminal amino group blocking agent is an exemplary terminal blocking agent for blocking terminals of polyimide or a precursor thereof, and specifically is a compound that reacts with an amino group of the diamine compound to produce a compound represented by Chemical Formula (41) or (51). In the following second step, the compound represented by Chemical Formula (41) or (51), a diamine compound, and a tetracarboxylic acid are reacted to produce a resin having the structure represented by Chemical Formula (3) or (5).

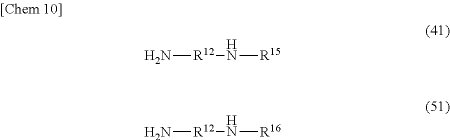

In Chemical Formula (41), R¹² represents a divalent diamine residue having two or more carbon atoms. R¹⁵ represents the structure represented by Chemical Formula (4). In Chemical Formula (51), R¹² represents a divalent diamine residue having two or more carbon atoms. R¹⁶ represents the structure represented by Chemical Formula (6) or the structure represented by Chemical Formula (7).

The second production method is a method of producing a resin having the structure represented by Chemical Formula (3) or (5) according to a two-step method as described below. Specifically, in the first step of the production method, a diamine compound and a tetracarboxylic acid are reacted to produce a resin having the structure represented by Chemical Formula (42). In the following second step, the resin having the structure represented by Chemical Formula (42) and the terminal amino group blocking agent as described above are reacted to produce a resin having the structure represented by Chemical Formula (3) or (5).

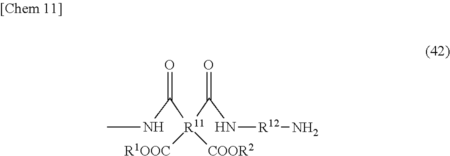

In Chemical Formula (42), R¹¹ and R¹² each are the same as R¹¹ and R¹² in Chemical Formula (10) as described above. R¹ and R², each independently, represent a hydrogen atom, a hydrocarbon group having 1 to 10 carbon atoms, an alkylsilyl group having 1 to 10 carbon atoms, an alkali metal ion, an ammonium ion, an imidazolium ion, or a pyridinium ion.

As the reaction solvent described above, for example, the solvents listed as specific examples of the solvent contained in the resin composition can be used alone or in combination of two or more. The amount of the reaction solvent used is preferably adjusted so that the total amount of the tetracarboxylic acid and the diamine compound is 0.1 to 50 mass % relative to the total reaction solution.

The reaction temperature is preferably from −20° C. to 150° C., and more preferably from 0° C. to 100° C. The reaction time is preferably from 0.1 to 24 hours, and more preferably from 0.5 to 12 hours.

A solution of the polyamic acid obtained as the polyimide precursor may be used as the resin composition as it is. In this case, the target resin composition can be obtained without isolating the resin by using the same solvent as used in the resin composition for the reaction solvent or by adding a solvent after completion of the reaction.

The polyamic acid obtained as described above may be further subjected to imidation or esterification of some repeating units of the polyamic acid. In this case, the polyamic acid solution obtained by polymerization of the polyamic acid may be directly used in the reaction, or the polyamic acid may be isolated and used in the reaction.

In addition, the resin composition preferably comprises at least one of a compound having the structure represented by Chemical Formula (8) and a compound having the structure represented by Chemical Formula (9). These compounds react with amine terminals of the polyamic acid during firing of the polyamic acid. Therefore, a resin composition comprising at least one of these compounds can be fired to obtain a resin (specifically, polyimide) having the structure represented by Chemical Formula (1) or (2) as described above without lowering the molecular weight of the polyamic acid.

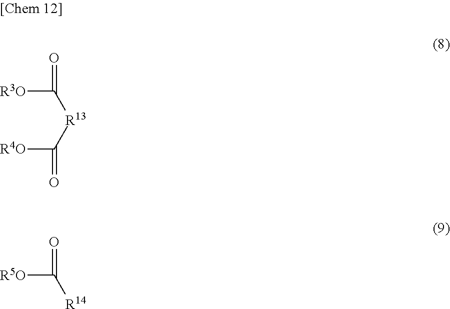

In Chemical Formula (8), R¹³ represents a divalent dicarboxylic acid residue having two or more carbon atoms. R³ and R⁴, each independently, represent a hydrogen atom, a hydrocarbon group having 1 to 10 carbon atoms, an alkylsilyl group having 1 to 10 carbon atoms, an alkali metal ion, an ammonium ion, an imidazolium ion, or a pyridinium ion. Specific examples of R¹³ include the structure described as a specific example of R¹³ in Chemical Formula (1) as described above. In Chemical Formula (9), R¹⁴ represents a monovalent monocarboxylic acid residue having one or more carbon atoms. R⁵ represents a hydrogen atom, a hydrocarbon group having 1 to 10 carbon atoms, an alkylsilyl group having 1 to 10 carbon atoms, an alkali metal ion, an ammonium ion, an imidazolium ion, or a pyridinium ion. Specific examples of R¹⁴ include the structure described as a specific example of R¹⁴ in Chemical Formula (2) as described above.

The amount of at least one of a compound having the structure represented by Chemical Formula (8) and a compound having the structure represented by Chemical Formula (9) contained in the resin composition is preferably 0.05 parts by mass or more, and more preferably 0.1 parts by mass or more, based on 100 parts by mass of the polyimide precursor in the resin composition. The amount is also preferably 5.0 parts by mass or less, and more preferably 3.0 parts by mass or less, based on 100 parts by mass of the polyimide precursor in the resin composition. When the amount is 0.05 parts by mass or more, amine terminals in the polyamic acid can be decreased, so that the electric charge change in film during light irradiation in the resin film comprising the polyimide can be prevented. When the amount is 5.0 mass or less, the decrease in the heat resistance of the resin film caused by the residual components that have not reacted with the amine terminals can be prevented.

The resin composition may also comprise, as necessary, at least one additives selected from a photoacid generator (a), a thermal crosslinking agent (b), a thermal acid generator (c), a compound comprising a phenolic hydroxy group (d), an adhesion improving agent (e), and a surfactant (f). Specific examples of such additives include those described in WO2017/099183.

### (Photoacid Generator (a))

The resin composition may be a photosensitive resin composition by including a photoacid generator (a). By including a photoacid generator (a), an acid will be generated at a light irradiated portion of the resin composition to increase the solubility of the light irradiated portion in an alkali aqueous solution, and thus a positive type relief pattern formed by dissolution of the light irradiated portion can be obtained. In addition, by including a photoacid generator (a) and an epoxy compound or a thermal crosslinking agent (b) described below, the acid generated in the light irradiated portion promotes the crosslinking reaction of the epoxy compound and the thermal crosslinking agent (b), and thus a negative type relief pattern in which the light irradiated portion is insolubilized can be obtained.

Examples of the photoacid generator (a) include quinonediazide compounds, sulfonium salts, phosphonium salts, diazonium salts, and iodonium salts. The resin composition may include two or more of these compounds, resulting in obtaining a highly sensitive photosensitive resin composition.

### (Thermal Crosslinking Agent (b))

When a thermal crosslinking agent (b) is included in the resin composition, the chemical resistance and hardness of the resin film obtained by heating can be improved. The amount of the thermal crosslinking agent (b) is preferably from 10 parts by mass to 100 parts by mass based on 100 parts by mass of the resin composition. When the amount of the thermal crosslinking agent (b) is from 10 parts by mass to 100 pats by mass, the obtained resin film has high strength and the resin composition has excellent storage stability.

### (Thermal Acid Generator (c))

The resin composition may further include a thermal acid generator (c). A thermal acid generator (c) generates an acid via heating after development described below, thereby promoting the crosslinking reaction between polyimide or a precursor thereof and a thermal crosslinking agent (b), as well as the curing reaction. As a result, the chemical resistance of the resulting heat-resistant resin film (specifically, a resin film comprising polyimide) is improved and film thinning is reduced. Preferably, the acid generated from the thermal acid generator (c) is a strong acid, for example, arylsulfonic acids, such as p-toluenesulfonic acid and benzenesulfonic acid; and alkylsulfonic acids, such as methanesulfonic acid, ethanesulfonic acid, and butanesulfonic acid. The amount of the thermal acid generator (c) is preferably 0.5 parts by mass or more, and is preferably 10 parts by mass or less, based on 100 parts by mass of the resin composition from the viewpoint of further promoting the crosslinking reaction.

### (Compound Comprising a Phenolic Hydroxy Group (d))

In order to compensate for the alkali developability of the photosensitive resin composition, as necessary, the resin composition may include a compound comprising a phenolic hydroxy group (d). By including the compound comprising a phenolic hydroxy group (d), the resulting photosensitive resin composition hardly dissolves in an alkaline developing solution before exposure to light and easily dissolves in the alkaline developing solution after exposure to light. This makes it possible to develop films easily, in a short time, with less film thinning due to development. Therefore, the sensitivity is likely to increase. The amount of such a compound comprising a phenolic hydroxy group (d) is preferably from 3 parts by mass to 40 parts by mass based on 100 parts by mass of the resin composition.

### (Adhesion Improving Agent (e))

The resin composition may include an adhesion improving agent (e). By including an adhesion improving agent (e), the adhesion of a base substrate, such as a silicon wafer, ITO, SiO₂, or silicon nitride, to the photosensitive resin composition when the photosensitive resin film is developed can be improved. In addition, the resistance to oxygen plasma and UV ozone treatment used in washing can be improved by improving the adhesion between the photosensitive resin composition and the base substrate. This can also prevent the film lifting phenomenon where the resin film lifts off from the substrate during firing or the vacuum process during display manufacturing. The content of the adhesion improving agent (e) is preferably from 0.005 parts by mass to 10 parts by mass based on 100 parts by mass of the resin composition.

### (Surfactant (f))

In order to improve the application properties, the resin composition may include a surfactant (f). Examples of the surfactant (f) include fluorochemical surfactants, such as “FLUORAD” (registered trademark) manufactured by Sumitomo 3M Limited, “MEGAFACE” (registered trademark), manufactured by DIC Corporation, and “SURUFURON” (registered trademark) manufactured by Asahi Glass Co., Ltd.; organosiloxane surfactants, such as KP341 manufactured by Shin-Etsu Chemical Co., Ltd., DBE manufactured by Chisso Corporation, and “POLYFLOW” (registered trademark) and “GRANOL” (registered trademark) manufactured by Kyoeisha Chemical Co. Ltd., and BYK manufactured by BYK-Chemie GmbH; and acrylic polymer surfactants, such as POLYFLOW manufactured by Kyoeisha Chemical Co., Ltd. The content of the surfactant (f) is preferably from 0.01 parts by mass to 10 parts by mass based on 100 parts by mass of the resin composition.

Examples of the method for dissolving the additives described above, such as a photoacid generator (a), a thermal crosslinking agent (b), a thermal acid generator (c), a compound comprising a phenolic hydroxy group (d), an adhesion improving agent (e), and a surfactant (f) to the resin composition include stirring and heating. When a photoacid generator (a) is included, the heating temperature is preferably determined within a range not impairing the performance as photosensitive resin composition. Usually, the temperature is room temperature to 80° C. In addition, the order of dissolving the components is not particularly limited. For example, a method of dissolving the components sequentially from a compound having low solubility may be used. A component that tends to generate air bubbles during dissolution by stirring, such as the surfactant (f), can be added last after dissolving the other components to prevent poor dissolution of the other components due to the generation of air bubbles.

A varnish, an example of the resin composition obtained by the above production method, is preferably filtered through a filter to remove foreign matters, such as dirt. The filter pore diameter is, for example, but not limited to, 10 μm, 3 μm, 1 μm, 0.5 μm, 0.2 μm, 0.1 μm, 0.07 μm, or 0.05 μm. Examples of the material of the filter include polypropylene (PP), polyethylene (PE), nylon (NY), and polytetrafluoroethylene (PTFE), and polyethylene and nylon are preferable.

### (Method of Producing Resin Film)

Next, the method of producing a resin film according to embodiments of the present invention will be described. The method of producing a resin film is an exemplary method of producing the resin film according to embodiments of the present invention using the resin composition described above. Specifically, the method of producing a resin film comprises an application step for applying a resin composition comprising polyimide or a polyimide precursor and a solvent to a support; and a heating step for heating the coating film obtained by the application step to obtain a resin film.

In the application step, a varnish, a resin composition according to the present invention, is first applied onto a support. Examples of the support include wafer substrates, such as silicon and gallium arsenide, glass substrates, such as sapphire glass, soda-lime glass, and alkali-free glass, metal substrates or metal foils, such as stainless steel and copper, and ceramic substrates. Especially, alkali-free glass is preferable from the viewpoint of surface smoothness and dimensional stability during heating.

Examples of the method for applying the varnish include a spin coating method, a slit coating method, a dip coating method, a spray coating method, and a printing method. These methods may be used in combination. When the resin film is used as a substrate for a display (for example, a substrate for a semiconductor element such as TFT provided in a display), the resin composition is required to be applied onto a large-sized support, and thus a slit coating method is particularly preferably employed.

Before the application step, the support may be pretreated. Examples of the pretreatment include a method for treating the support surface with a solution in which 0.5 mass % to 20 mass % of a pretreatment agent is dissolved in a solvent such as isopropanol, ethanol, methanol, water, tetrahydrofuran, propylene glycol monomethyl ether acetate, propylene glycol monomethyl ether, ethyl lactate, and diethyl adipate, by a method of spin coating, slit die coating, bar coating, dip coating, spray coating, or steam treatment The pretreated support, as necessary, may also be subjected to a vacuum drying process, and thereafter may be subjected to heat treatment at 50° C. to 300° C. to promote the reaction between the support and the pretreatment agent.

After the application step, the coating film is generally dried. As the drying method, drying under reduced pressure, drying by heating, or a combination thereof may be used. The method for drying under reduced pressure is carried out by, for example, placing the support on which a coating film is formed in a vacuum chamber and reducing the pressure inside the vacuum chamber to dry the coating film. The method for drying by heating may include drying the coating film using a hot plate, an oven, infrared radiation, or the like. When a hot plate is used, the support on which the coating film is formed is held directly on the plate or on jigs such as proximity pins placed on the plate, and then the coating film is dried by heating. The heating temperature may vary depending on the type of the solvent used in the varnish and the purpose. Heating is preferably carried out for 1 minute to several hours at a temperature ranging from room temperature to 180° C.

When the resin composition to be applied includes a photoacid generator (a), the coating film after drying can be subjected to pattern formation by the method described below. For example, the method comprises irradiating the coating film with an actinic ray through a mask having a desired pattern for exposure of the coating film. Examples of the actinic ray used for the exposure include ultraviolet rays, visible rays, electron rays, and X-rays. In the present invention, the i-line (365 nm), h-line (405 nm), and g-line (436 nm) of mercury lamps are preferably used. When the coating film has positive photosensitivity, the exposed portion in the coating film is dissolved in the developing solution. When the coating film has negative photosensitivity, the exposed portion is cured and becomes insoluble in the developing solution.

After exposure, a desired pattern is formed in the coating film by removing the exposed portion in the case of the positive type coating film or removing the unexposed portion in the case of the negative type coating film using a developing solution. Preferably, the developing solution is an aqueous solution of an alkaline compound, such as tetramethylammonium for both positive and negative type coating films. In some cases, polar solvents such as N-methyl-2-pyrrolidone, alcohols, esters, ketones, and the like may be added to the aqueous alkali solution alone or in combination of two or more.

Thereafter, a heating step for heat treating the coating film on the support to produce a resin film is carried out. In this heating step, the coating film is heat treated and fired at a temperature ranging from 180° C. to 600° C., preferably from 220° C. to 600° C., more preferably from 420° C. to 490° C. This results in a resin film produced on the support. When the heating temperature (firing temperature) for the coating film in the heating step is 220° C. or higher, imidation proceeds sufficiently to give a resin film having excellent mechanical properties. When the heating temperature is 420° C. or higher, a resin film having excellent heat resistance is obtained. When the heating temperature is 490° C. or lower, a resin film in which charge transfer transition is less likely to occur is obtained. Thus, when the heating temperature is from 420° C. to 490° C., the electric charge change in film during light irradiation in a resin film that is excellent in mechanical properties and heat resistance, such as a resin film comprising polyimide, can be more easily reduced.

The resin film obtained through the application step, heating step, and other steps described above can be used after being separated from the support, or directly used without being separated from the support.

Examples of the separation method include mechanical separation, immersion in water, immersion in a chemical solution such as hydrochloric acid or hydrofluoric acid, and irradiation of the interface between the resin film and the support with laser light in the wavelength range of ultraviolet to infrared light. In particular, in the case where separation is performed after a device is prepared on the resin film comprising polyimide, separation using an ultraviolet laser is preferable because of the need of separation without damaging the device. For easy separation, the support may be previously coated with a mold release agent or provided with a sacrificial layer before application of the resin composition to the support. Examples of the mold release agent include silicone-based, fluorine-based, aromatic polymer-based, and alkoxy silane-based mold release agents. Examples of the sacrificial layer include metal films, metal oxide films, and amorphous silicon films.

The thickness of the resin film according to embodiments of the present invention is not particularly limited, and is preferably 4 μm or more, more preferably 5 or more, and still more preferably 6 μm or more. The thickness of the resin film is preferably 40 μm or less, more preferably 30 μm or less, and still more preferably 25 or less. When the thickness of the resin film is 4 μm or more, sufficient mechanical properties as a substrate for a semiconductor element are obtained. When the thickness of the resin film is 40 μm or less, sufficient toughness as a substrate for a semiconductor element is obtained.

The 0.05% weight loss temperature of the resin film according to embodiments of the present invention is not particularly limited, and is preferably 490° C. or higher, and more preferably 495° C. or higher. When the 0.05% weight loss temperature of the resin film is 490° C. or higher, the film lifting phenomenon where the inorganic film formed on the resin film lifts off from the film surface due to high-temperature processes during device production can be prevented.

The light transmittance at a wavelength of 470 nm of the resin film according to embodiments of the present invention when the thickness of the resin film is set to 10 μm is not particularly limited, and is preferably 60% or more, and more preferably 65% or more. When the light transmittance is 60% or more, the resin film is hardly photoexcited, so that the electric charge change in film during light irradiation in the resin film can be more easily reduced.

### (Electronic Device)

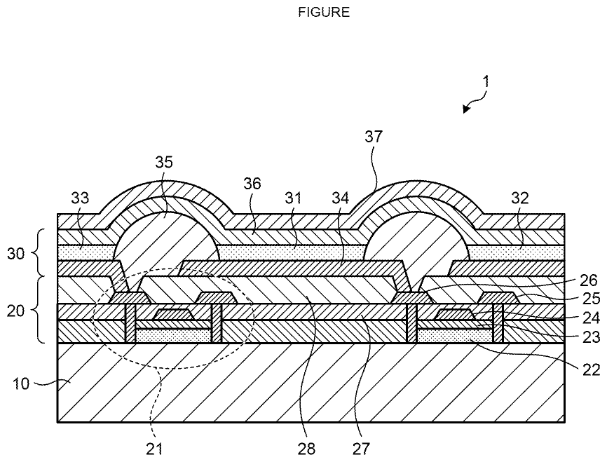

Next, the electronic device according to embodiments of the present invention will be described. The FIGURE is a schematic cross-sectional view showing an exemplary electronic device according to embodiments of the present invention. As shown in FIG. 1, the electronic device 1 comprises a resin film 10, and a semiconductor element 21 formed on the resin film 10. In addition, the electronic device 1, when it is, for example, an image display device, further comprises image display elements 31-33.

The resin film 10 is a resin film according to embodiments of the present invention, and serves as a substrate (e.g., flexible substrate) of the electronic device 1 as shown in the FIGURE. The semiconductor element 21 is formed on the resin film 10 as shown in the FIGURE. The semiconductor element 21 is, for example, a thin-film transistor (TFT), and comprises a semiconductor layer 22, a gate insulating layer 23, a gate electrode 24, a drain electrode 25, and a source electrode 26 as shown in the FIGURE. The semiconductor layer 22 is provided between the drain electrode 25 and the source electrode 26. The gate insulating layer 23 electrically insulates the semiconductor layer 22 from the gate electrode 24. In addition, an interlayer insulating layer 27 is provided between the gate electrode 24 and the drain and source electrodes 25 and 26, which interlayer insulating layer 27 can electrically insulate these electrodes. An interlayer insulating layer 28 is provided on the drain electrode 25 and the source electrode 26. The electronic device 1 comprises an element layer 20 on the resin film 10, the element layer 20 comprising a plurality of the semiconductor elements 21, and the interlayer insulating layers 27 and 28.

In addition, the electronic device 1 comprises a light emitting layer 30 on the element layer 20 as shown in the FIGURE. The light emitting layer 30 comprises a plurality of image display elements 31-33, a pixel electrode 34, a bank 35, a counter electrode 36, and a sealing film 37. The image display elements 31-33 each are an element that emits light with a color required for image display. For example, when the electronic device 1 is an organic EL display, the image display elements 31-33 are organic EL elements that emit red light, green light, and blue light, respectively. These image display elements 31-33 each are electrically connected to the source electrode 26 of the semiconductor element 21 via the pixel electrode 34. The pixel electrode 34 in the light emitting layer 30 is electrically insulated from the drain electrode 25 in the element layer 20 by the interlayer insulating layer 28. In addition, banks 35 are provided among the image display elements 31-33. A counter electrode 36 is formed on the image display elements 31-33 and the banks 35. A sealing film 37 is formed on the counter electrode 36, and protects the image display elements 31-35 and the like.

It is noted that the FIGURE illustrates an electronic device 1 that serves as an image display device, but the present invention is not limited thereto. For example, the electronic device 1 may be a device other than image display device, such as a touch panel. In this case, the electronic device 1 may comprise a component such as a touch panel unit on the element layer 20 in addition to the light emitting layer 30. Furthermore, the semiconductor element 21 included in the electronic device 1 is not restricted to TFT as shown in the FIGURE, and may be either a top-gate or bottom-gate TFT, or may be other semiconductor elements than TFT. In addition, any numbers of semiconductor elements and image display elements may be placed in the electronic device 1 in the present invention.

### (Method of Manufacturing Electronic Device)

Next, the method of manufacturing the electronic device according to embodiments of the present invention will be described. An exemplary method of manufacturing an electronic device comprising the resin film according to embodiments of the present invention as a substrate will be described below with reference to the electronic device 1 illustrated in the FIGURE as appropriate. The method of manufacturing an electronic device comprises: a film production step for producing a resin film on a support by the method of producing a resin film as described above; an element formation step for forming a semiconductor element on the resin film; and a separation step for separating the resin film (specifically, the resin film with the semiconductor element formed thereon) from the support.

First, in the film production step, the resin film as described above is produced on a support, such as glass substrate, by performing an application step, a heating step, and other steps according to the method of producing a resin film as described above. The thus-produced resin film can be used as a substrate for a semiconductor element in an electronic device (hereinafter referred to as “element substrate” as appropriately) either in the state of being formed on the support or being separated from the support. In addition, an inorganic film is provided on the resin film, as necessary. This can prevent water and oxygen outside the substrate from permeating through the resin film and causing deterioration of pixel driving elements and light-emitting elements. Examples of the inorganic film include silicon oxide (SiOx), silicon nitride (SiNy), and silicon oxide nitride (SiOxNy). The inorganic film can be used to form a single layer, or two or more inorganic films can be stacked to form a multiple layer. The inorganic film can also be used such that it is alternately stacked with an organic film such as polyvinyl alcohol. A method for forming the inorganic film is preferably carried out using a deposition method, such as chemical vapor deposition (CVD) or physical vapor deposition (PVD). A resin film can be formed on the inorganic film, or an inorganic film can be further formed on the resin film, as necessary, to produce an element substrate comprising multiple layers of the inorganic and resin films. The same resin composition is preferably used to produce the resin films from the viewpoint of simplifying the process.

Thereafter, in the element formation step, a semiconductor element is formed on the resin film obtained as described above. Specifically, in the case that the semiconductor element is TFT, a TFT such as top-gate TFT or bottom-gate TFT is formed on the resin film. For example, in the case where the semiconductor element is a top-gate TFT, a semiconductor layer 22, a gate insulating layer 23, and a gate electrode 24 are formed on a resin film 10, and then an interlayer insulating layer 27 is formed to cover them, as shown in the FIGURE. Thereafter, contact holes are formed in the interlayer insulating layer 27. Then, a pair of a drain electrode 25 and a source electrode 26 is formed such that they fill the contact holes. Further, an interlayer insulating layer 28 is formed to cover them.

The semiconductor layer (e.g., semiconductor layer 22 as illustrated in the FIGURE) includes a channel region (active layer) in the region opposite to the gate electrode. The semiconductor layer may be composed of low temperature polycrystalline silicon (LTPS), amorphous silicon (a-Si), or the like, or may be composed of an oxide semiconductor, such as indium tin zinc oxide (ITZO), indium gallium zinc oxide (IGZO: InGaZnO), zinc oxide (ZnO), indium zinc oxide (IZO), indium gallium oxide (IGO), indium tin oxide (ITO), or indium oxide (InO). When forming such a semiconductor layer, the resin film and other structures is commonly subjected to a high temperature process. For example, in the case of LTPS formation, a-Si may be formed, followed by annealing, for example, at 450° C. for 120 minutes for the purpose of dehydrogenation. Such a high temperature process, when the heat resistance of the resin film is insufficient, may damage the TFT by, for example, causing the inorganic film on the resin film to lift off and destroying the semiconductor layer.

Preferably, the gate insulating layer (e.g., the gate insulating layer 23 as illustrated in the FIGURE) comprises a single-layer film composed of one of, for example, silicon oxide (SiOx), silicon nitride (SiNx), silicon oxide nitride (SiON), and aluminum oxide (AlOx), or a multi-layer film composed of two or more of them.

The gate electrode (e.g., the gate electrode 24 as illustrated in the FIGURE) controls the carrier density in the semiconductor layer based on the applied gate voltage, as well as serves as a voltage supplying wiring. Examples of the material for constituting the gate electrode include single metals and alloys thereof, comprising at least one of titanium (Ti), tungsten (W), tantalum (Ta), aluminum (Al), molybdenum (Mo), silver (Ag), neodymium (Nd), and copper (Cu). Alternatively, the material for constituting the gate electrode may be a compound comprising at least one of them, or a multi-layer film comprising two or more of them. The material for constituting the gate electrode to be used may be, for example, a transparent electrically conductive film such as ITO.

The interlayer insulating layer (e.g., the interlayer insulating layers 27, 28 as illustrated in the FIGURE) is composed of, for example, an organic material such as an acrylic resin, polyimide (PI), or a novolac resin. Alternatively, inorganic materials such as silicon oxide films, silicon nitride films, silicon oxide nitride films, and aluminum oxide may be used in the interlayer insulating layer.

The source electrode and drain electrode (e.g., the source electrode 26 and the drain electrode 25 as illustrated in the FIGURE) each serve as a source or a drain in TFT. The source electrode and drain electrode comprise, for example, the same metal or transparent electrically conductive film as listed as the material for constituting the gate electrode as described above. Materials having good electroconductivity are desirably selected as the source electrode and the drain electrode.

TFTs obtained as exemplary semiconductor elements as described above can be used in image display devices such as organic EL displays, liquid crystal displays, electronic papers, and μLED displays. When the electronic device in the present invention is an organic EL display, an image display element to be used in the organic EL display is formed on a TFT according to the following procedure. Specifically, a pixel electrode, an organic EL element, a counter electrode, and a sealing film are formed on a TFT in this order. The pixel electrode is connected, for example, to the source electrode and drain electrode as described above. The counter electrode is configured to supply a common cathode voltage to pixels through, for example, wires or the like. The sealing film (e.g., the sealing film 37 as illustrated in the FIGURE) is a layer for protecting the organic EL element from the outside. This sealing film may be composed of, for example, inorganic materials such as silicon oxide (SiOx), silicon nitride (SiNx), and silicon oxide nitride (SiON), or other organic materials.

Finally, in the separation step, the resin film with the semiconductor element formed thereon as described above is separated from the support to produce an electronic device comprising the resin film. Examples of the method for separating the support and the resin film at the interface therebetween include methods using lasers, mechanical separation methods, and methods comprising etching the support. In the method using lasers, a support, such as a glass substrate, can be irradiated with a laser from the side without a semiconductor element formed to separate the support and the resin film without damaging the semiconductor element. A primer layer for easily separating the support and the resin film may also be provided between the support and the resin film. The laserbeam used can be a laserbeam having a wavelength ranging from UV to infrared, and especially UV light is preferable. More preferred laserbeam is 308-nm excimer laser. The separation energy for separating the support and the resin film is preferably 250 mJ/cm² or less, and more preferably 200 mJ/cm² or less.

### EXAMPLE

Hereinafter, the present invention will be described with reference to Examples and the like. However, the present invention is not limited to Examples and the like described below. First, the evaluations, measurements, tests, and the like performed in Examples and Comparative Examples below will be described.

### (Section 1: Electric Charge Change in Film of Resin Film)

In the section 1, the measurement of the electric charge change in film of the resin film will be described. In the measurement method, a laminate comprising the resin film and a Si wafer with a thermal oxide film was prepared for each of the resin films obtained in Examples. Using the prepared laminate, the measurement of the electric charge change in film was performed according to the following procedure.

First, the laminate as a measurement sample was placed on an electrode as the measurement stage in a dark chamber such that the Si wafer side was in contact with the electrode. Then, the resin film of the placed laminate was contacted with a mercury probe having an electrode area of 0.026 cm² to form a capacitor structure comprising the resin film. Next, a DC bias voltage and an AC voltage were applied to the capacitor structure to determine the CV characteristics of the capacitor structure. Based on the results obtained from the determination of the CV characteristics, the flat band voltage V_{FB}1 [V] and the capacitance in charge storage state C₁ [F] of the capacitor structure were determined. The measurement conditions for the CV characteristics were as follows: the AC frequency was set to 100 kHz, and the DC bias voltage (sweep voltage) was set to −60 V to +60 V.

Thereafter, the mercury probe was detached from the resin film of the laminate, and the resin film was irradiated with a light having a wavelength of 470 nm and an intensity of 4.0 μW/cm² for 30 minutes. After the completion of the light irradiation to the resin film, the mercury probe was contacted again with the resin film, and the CV characteristics were determined in the same manner as described above. Based on the obtained results from the determination of the CV characteristics, the flat band voltage after light irradiation V_{FB}2 [V] was determined.

Using the flat band voltage before and after light irradiation V_{FB}1 and V_{FB}2, the capacitance C₁, the elementary charge q, the electrode area of the mercury probe S, and the thickness of the resin film t obtained as described above, the electric charge change in film Q of the resin film to be measured was calculated according to the Formulae (F1) and (F2) described above.

### (Section 2: Light Transmittance of Resin Film)

In the section 2, the measurement of the light transmittance of the resin film will be described. In the measurement method, a laminate comprising the resin film and a glass substrate for each of the resin films obtained in Examples. Using the prepared laminate, the light transmittance of the resin film was measured with an ultraviolet and visible spectrophotometer (MultiSpec 1500, manufactured by Shimadzu Corporation) at a wavelength of 470 nm.

### (Section 3: 0.05% Weight Loss Temperature of Resin Film)

In the section 3, the measurement of the 0.05% weight loss temperature of the resin film will be described. In the measurement method, the 0.05% weight loss temperature of the resin film (sample) obtained in Examples was measured using a thermogravimetric analyzer (TGA-50, manufactured by Shimadzu Corporation). In the step 1 in the method, a sample was heated to 150° C. at a heating rate of 10° C./min to remove adsorption water from the sample. In the following step 2, the sample was air-cooled to room temperature at a cooling rate of 10° C./min. In the following step 3, the 0.05% weight loss temperature of the sample was measured at a heating rate of 10° C./min.

### (Section 4: CTE of Resin Film)

In the section 4, the measurement of the CTE of the resin film will be described. In the measurement method, the CTE of the resin film (sample) obtained in Examples was measured using a thermomechanical analyzer (EXSTAR6000TMA/S S6000, manufactured by SII NanoTechnology Inc.). In the step 1 in the method, a sample was heated to 150° C. at a heating rate of 5° C./min to remove adsorption water from the sample. In the following step 2, the sample was air-cooled to room temperature at a cooling rate of 5° C./min. In the following step 3, the CTE of the sample was measured at a heating rate of 5° C./min. The target CTE of the resin film was determined in the temperature range from 50° C. to 150° C. in the measurement method.

### (Section 5: Estimation of Film Lifting)

In the section 5, the estimation of film lifting will be described. In this estimation method, a laminate comprising the resin film and a glass substrate for each of the resin films obtained in Examples. Using the prepared laminate, a SiO film having a thickness of 50 nm was formed on the resin film by CVD and then heated at 450° C. for 120 minutes. Thereafter, the number of film lifting where the SiO film lifted off from the resin film was determined visually and by light microscopy.

### (Section 6: Reliability Test for TFT)

In the section 6, the reliability test for TFT will be described. In this test, the organic EL displays obtained in Examples were used to measure the amount of change ΔVth between the initial threshold voltage Vth₀ and the threshold voltage after 1-hour operation Vth₁=Vth₁−Vth₀ with a semiconductor device analyzer (B1500A, manufactured by Agilent). Smaller measurement of the amount of change ΔVth means that the reliability of TFT is maintained for a longer period of time. As the operation conditions for the TFTs, the drain voltage Vd was set to 15 V, the source voltage Vs was set to 0 V, and the gate voltage Vg was set to 15 V.

### (Compound)

The compounds as shown below are used as appropriate in Examples and Comparative Examples. The compounds used as appropriate in Examples and Comparative Examples and their abbreviations are as shown below.

PMDA: pyromellitic dianhydride

BPDA: 3,3′,4,4′-biphenyltetracarboxylic dianhydride

PDA: p-phenylenediamine

BPAF: 9,9-bis(3,4-dicarboxyphenyl)fluorene dianhydride

CHDA: trans-1,4-cyclohexanediamine

DIBOC: di-tert-butyl dicarbonate

NMP: N-methyl-2-pyrrolidone

### Synthesis Example 1

A varnish of Synthesis Example 1 will be described. In Synthesis Example 1, a 300-mL four-neck flask was equipped with a thermometer and a stirring rod with a stirring blade. Subsequently, 160 g of NMP was charged into the flask under dry nitrogen gas flow and the temperature was raised to 40° C. After the temperature rising, 8.84 g (81.7 mmol) of PDA was charged with stirring. After checking the dissolution, 0.54 g (2.5 mmol) of DIBOC diluted in 10 g of NMP was added dropwise over 10 minutes. After 1 hour from completion of the dropwise addition, 9.76 g (33.2 mmol) of BPDA and 10.86 g (49.8 mmol) of PMDA were charged and stirred for 12 hours. The reaction solution was cooled to room temperature and filtered through a filter having a filter pore diameter of 0.2 μm to prepare the varnish.

### Synthesis Example 2

A varnish of Synthesis Example 2 will be described. In Synthesis Example 2, a 300-mL four-neck flask was equipped with a thermometer and a stirring rod with a stirring blade. Subsequently, 160 g of NMP was charged into the flask under dry nitrogen flow and the temperature was raised to 40° C. After the temperature rising, 7.85 g (72.6 mmol) of PDA was charged with stirring. After checking the dissolution, 0.48 g (2.2 mmol) of DIBOC diluted in 10 g of NMP was added dropwise over 10 minutes. After 1 hour from completion of the dropwise addition, 21.67 g (73.7 mmol) of BPDA was charged and stirred for 12 hours. The reaction solution was cooled to room temperature and filtered through a filter having a filter pore diameter of 0.2 μm to prepare the varnish.

### Synthesis Example 3

A varnish of Synthesis Example 3 will be described. In Synthesis Example 3, a 300-mL four-neck flask was equipped with a thermometer and a stirring rod with a stirring blade. Subsequently, 160 g of NMP was charged into the flask under dry nitrogen flow and the temperature was raised to 40° C. After the temperature rising, 8.17 g (71.5 mmol) of CHDA was charged with stirring. After checking the dissolution, 0.48 g (2.2 mmol) of DIBOC diluted in 10 g of NMP was added dropwise over 10 minutes. After 1 hour from completion of the dropwise addition, 21.36 g (72.6 mmol) of BPDA was charged and stirred for 12 hours. The reaction solution was cooled to room temperature and filtered through a filter having a filter pore diameter of 0.2 μm to prepare the varnish.

### Synthesis Example 4

A varnish of Synthesis Example 4 will be described. In Synthesis Example 4, a 300-mL four-neck flask was equipped with a thermometer and a stirring rod with a stirring blade. Subsequently, 160 g of NMP was charged into the flask under dry nitrogen flow and the temperature was raised to 40° C. After the temperature rising, 6.32 g (58.4 mmol) of PDA was charged with stirring. After checking the dissolution, 0.39 g (1.8 mmol) of DIBOC diluted in 10 g of NMP was added dropwise over 10 minutes. After 1 hour from completion of the dropwise addition, 6.98 g (23.7 mmol) of BPDA and 16.31 g (35.6 mmol) of BPAF were charged and stirred for 12 hours. The reaction solution was cooled to room temperature and filtered through a filter having a filter pore diameter of 0.2 μm to prepare the varnish.

### Synthesis Example 5

A varnish of Synthesis Example 5 will be described. In Synthesis Example 5, a 300-mL four-neck flask was equipped with a thermometer and a stirring rod with a stirring blade. Subsequently, 160 g of NMP was charged into the flask under dry nitrogen flow and the temperature was raised to 40° C. After the temperature rising, 8.84 g (81.7 mmol) of PDA was charged with stirring. After checking the dissolution, 0.54 g (2.5 mmol) of DIBOC diluted in 10 g of NMP was added dropwise over 10 minutes. After 1 hour from completion of the dropwise addition, 9.76 g (33.2 mmol) of BPDA and 10.86 g (49.8 mmol) of PMDA were charged and stirred for 12 hours. After the reaction solution was cooled to room temperature, 0.45 g (2.7 mmol) of phthalic acid was added. Finally, the resultant was filtered through a filter having a filter pore diameter of 0.2 μm to prepare the varnish.

### Synthesis Example 6

A varnish of Synthesis Example 6 will be described. In Synthesis Example 6, a 300-mL four-neck flask was equipped with a thermometer and a stirring rod with a stirring blade. Subsequently, 170 g of NMP was charged into the flask under dry nitrogen flow and the temperature was raised to 40° C. After the temperature rising, 9.00 g (83.2 mmol) of PDA was charged with stirring. After checking the dissolution, 9.94 g (33.8 mmol) of BPDA and 11.06 g (50.7 mmol) of PMDA were charged and stirred for 12 hours. After the reaction solution was cooled to room temperature, 0.45 g (2.7 mmol) of phthalic acid was added. Finally, the resultant was filtered through a filter having a filter pore diameter of 0.2 μm to prepare the varnish.

### Synthesis Example 7

A varnish of Synthesis Example 7 will be described. In Synthesis Example 7, the varnish was obtained in the same manner as in Synthesis Example 5 except that the amount of phthalic acid added was changed to 2.1 g (12.6 mmol).

### Synthesis Example 8

A varnish of Synthesis Example 8 will be described. In Synthesis Example 8, a 300-mL four-neck flask was equipped with a thermometer and a stirring rod with a stirring blade. Subsequently, 160 g of NMP was charged into the flask under dry nitrogen flow and the temperature was raised to 40° C. After the temperature rising, 8.89 g (82.2 mmol) of PDA was charged with stirring. After checking the dissolution, 0.89 g (4.1 mmol) of DIBOC diluted in 10 g of NMP was added dropwise over 10 minutes. After 1 hour from completion of the dropwise addition, 9.58 g (32.5 mmol) of BPDA and 10.65 g (48.8 mmol) of PMDA were charged and stirred for 12 hours. The reaction solution was cooled to room temperature and filtered through a filter having a filter pore diameter of 0.2 μm to prepare the varnish.

### Synthesis Example 9

A varnish of Synthesis Example 9 will be described. In Synthesis Example 9, a 300-mL four-neck flask was equipped with a thermometer and a stirring rod with a stirring blade. Subsequently, 170 g of NMP was charged into the flask under dry nitrogen flow and the temperature was raised to 40° C. After the temperature rising, 9.00 g (83.2 mmol) of PDA was charged with stirring. After checking the dissolution, 9.94 g (33.8 mmol) of BPDA and 11.06 g (50.7 mmol) of PMDA were charged and stirred for 12 hours. The reaction solution was cooled to room temperature and filtered through a filter having a filter pore diameter of 0.2 μm to prepare the varnish.

### Synthesis Example 10

A varnish of Synthesis Example 10 will be described. In Synthesis Example 10, a 300-mL four-neck flask was equipped with a thermometer and a stirring rod with a stirring blade. Subsequently, 160 g of NMP was charged into the flask under dry nitrogen flow and the temperature was raised to 40° C. After the temperature rising, 8.28 g (76.6 mmol) of PDA was charged with stirring. After checking the dissolution, 0.56 g (2.6 mmol) of DIBOC diluted in 10 g of NMP was added dropwise over 10 minutes. After 1 hour from completion of the dropwise addition, 10.02 g (34.0 mmol) of BPDA and 11.14 g (51.1 mmol) of PMDA were charged and stirred for 12 hours. The reaction solution was cooled to room temperature and filtered through a filter having a filter pore diameter of 0.2 μm to prepare the varnish.

### Synthesis Example 11

A varnish of Synthesis Example 11 will be described. In Synthesis Example 11, a 300-mL four-neck flask was equipped with a thermometer and a stirring rod with a stirring blade. Subsequently, 170 g of NMP was charged into the flask under dry nitrogen flow and the temperature was raised to 40° C. After the temperature rising, 8.15 g (75.4 mmol) of PDA was charged with stirring. After checking the dissolution, 21.85 g (74.3 mmol) of BPDA was charged and stirred for 12 hours. The reaction solution was cooled to room temperature and filtered through a filter having a filter pore diameter of 0.2 μm to prepare the varnish.

### Synthesis Example 12

A varnish of Synthesis Example 12 will be described. In Synthesis Example 12, a 300-mL four-neck flask was equipped with a thermometer and a stirring rod with a stirring blade. Subsequently, 160 g of NMP was charged into the flask under dry nitrogen flow and the temperature was raised to 40° C. After the temperature rising, 8.88 g (82.1 mmol) of PDA was charged with stirring. After checking the dissolution, 0.41 g (2.5 mmol) of phthalic anhydride diluted in 10 g of NMP was added dropwise over 10 minutes. After 1 hour from completion of the dropwise addition, 9.81 g (33.3 mmol) of BPDA and 10.90 g (50.0 mmol) of PMDA were charged and stirred for 12 hours. The reaction solution was cooled to room temperature and filtered through a filter having a filter pore diameter of 0.2 μm to prepare the varnish.

### Synthesis Example 13

A varnish of Synthesis Example 13 will be described. In Synthesis Example 13, a 300-mL four-neck flask was equipped with a thermometer and a stirring rod with a stirring blade. Subsequently, 170 g of NMP was charged into the flask under dry nitrogen flow and the temperature was raised to 40° C. After the temperature rising, 8.06 g (74.6 mmol) of PDA was charged with stirring. After checking the dissolution, 21.94 g (74.6 mmol) of BPDA was charged and stirred for 12 hours. The reaction solution was cooled to room temperature and filtered through a filter having a filter pore diameter of 0.2 μm to prepare the varnish.

### Synthesis Example 14

A varnish of Synthesis Example 14 will be described. In Synthesis Example 14, a 300-mL four-neck flask was equipped with a thermometer and a stirring rod with a stirring blade. Subsequently, 170 g of NMP was charged into the flask under dry nitrogen flow and the temperature was raised to 40° C. After the temperature rising, 7.97 g (73.7 mmol) of PDA was charged with stirring. After checking the dissolution, 22.03 g (74.9 mmol) of BPDA was charged and stirred for 12 hours. The reaction solution was cooled to room temperature and filtered through a filter having a filter pore diameter of 0.2 μm to prepare the varnish.

### Synthesis Example 15

A varnish of Synthesis Example 15 will be described. In Synthesis Example 15, a 300-mL four-neck flask was equipped with a thermometer and a stirring rod with a stirring blade. Subsequently, 170 g of NMP was charged into the flask under dry nitrogen flow and the temperature was raised to 40° C. After the temperature rising, 9.21 g (85.2 mmol) of PDA was charged with stirring. After checking the dissolution, 9.65 g (32.8 mmol) of BPDA and 11.14 g (51.1 mmol) of PMDA were charged and stirred for 12 hours. The reaction solution was cooled to room temperature and filtered through a filter having a filter pore diameter of 0.2 μm to prepare the varnish.

The compositions of the varnishes obtained in Synthesis Examples 1 to 15 were shown in Tables 1-1 and 1-2.

TABLE 1-1

| | | Synthesis | Synthesis | Synthesis | Synthesis | Synthesis | Synthesis | Synthesis | Synthesis |
|---|---|---|---|---|---|---|---|---|---|
| Synthesis Example | | Example 1 | Example 2 | Example 3 | Example 4 | Example 5 | Example 6 | Example 7 | Example 8 |
| Diamine | PDA | 98.5 | 98.5 | | 98.5 | 98.5 | 98.5 | 98.5 | 101 |
| (molar ratio) | CHDA | | | 98.5 | | | | | |
| Acid | PMDA | 60 | | | | 60 | 60 | 60 | 60 |
| dianhydride | BPDA | 40 | 100 | 100 | 40 | 40 | 40 | 40 | 40 |
| (molar ratio) | BPAF | | | | 60 | | | | |
| Molar ratio of acid dianhydride | | 1.015 | 1.015 | 1.015 | 1.015 | 1.015 | 1.015 | 1.015 | 0.990 |
| compound/molar ratio of diamine | | | | | | | | | |
| compound | | | | | | | | | |
| Terminal blocking agent | DIBOC | 3 | 3 | 3 | 3 | 3 | | 3 | 5 |
| (molar ratio) | Phthalic anhydride | | | | | | | | |
| Additives (% mass*) | Phthalic acid | | | | | 1.5 | 1.5 | 7 | |

*Polyimide or a precursor thereof is considered as 100% mass.

TABLE 1-2

| | | Synthesis | Synthesis | Synthesis | Synthesis | Synthesis | Synthesis | Synthesis |
|---|---|---|---|---|---|---|---|---|
| Synthesis Example | | Example 9 | Example 10 | Example 11 | Example 12 | Example 13 | Example 14 | Example 15 |
| Diamine | PDA | 98.5 | 90 | 100 | 98.5 | 100 | 98.5 | 100 |
| (molar ratio) | CHDA | | | | | | | |
| Acid | PMDA | 60 | 60 | | 60 | | | 60 |
| dianhydride | BPDA | 40 | 40 | 98.5 | 40 | 100 | 100 | 38.5 |
| (molar ratio) | BPAF | | | | | | | |
| Molar ratio of acid dianhydride | | 1.015 | 1.111 | 0.985 | 1.015 | 1 | 1.015 | 0.985 |
| compound/molar ratio of diamine | | | | | | | | |
| compound | | | | | | | | |
| Terminal blocking agent | DIBOC | | 3 | | | | | |
| (molar ratio) | Phthalic anhydride | | | | 3 | | | |
| Additives (% mass*) | Phthalic acid | | | | | | | |

*Polyimide or a precursor thereof is considered as 100% mass.

### Example 1

In Example 1, the varnish obtained in Synthesis Example 1 was used and evaluated as described below. In the case where a coating film with a desired thickness was failed to be formed, the varnish was diluted with NMP as necessary before use.

First, the varnish of Synthesis Example 1 was applied to the thermal oxide film surface of a P-type Si wafer with a thermal oxide film having a thickness of 50 nm using a spin coater. Then, the coating film of the varnish was heated using a gas oven (INH-21CD, manufactured by Koyo Thermo Systems Co., Ltd.) under a nitrogen atmosphere (with an oxygen concentration of 100 ppm or less) at 400° C. for 30 minutes to form a resin film having a thickness of 0.7 μm on the P-type Si wafer with the thermal oxide film. Using the laminate of the resulting resin film and the P-type Si wafer with a thermal oxide film, the electric charge change in film of the resin film was measured according to the method described in the section 1 above.

In addition, the varnish of Synthesis Example 1 was applied to an alkali-free glass substrate (AN-100, manufactured by Asahi Glass Co., Ltd.) having 100 mm height×100 mm width×0.5 mm thickness. Then, the coating film of the varnish was heated under the same conditions as the heating conditions described above. A resin film having a thickness of 10 μm was thus formed on the glass substrate. Using the laminate of the resulting resin film and the glass substrate, the light transmittance of the resin film was measured according to the method described in the section 2 above.

Thereafter, the glass substrate was immersed in hydrofluoric acid for 4 minutes to separate the resin film from the glass substrate. The separated product was dried in the air to obtain the resin film. Using the resulting resin film, the measurement of the 0.05% weight loss temperature of the resin film according to the method described in the section 3 above and the measurement of the CTE of the resin film according to the method described in the section 4 above were performed.

Thereafter, using the laminate of the resin film before being separated from the glass substrate and the glass substrate, the film lifting was evaluated according to the method described in the section 5.

Thereafter, a SiO film was formed on the resin film before being separated from the glass substrate by a CVD method. Then, TFT was formed on the SiO film. Specifically, a semiconductor layer was formed and then patterned into a predetermined shape by photolithography and etching. Thereafter, a gate insulating layer was formed on the semiconductor layer by a CVD method. Then, a gate electrode was patterned on the gate insulating layer. The gate insulating layer was etched through the gate electrode as a mask for patterning of the gate insulating layer. Thereafter, an interlayer insulating layer was formed to cover the gate electrode and others. Then, contact holes were formed in an area opposite to a portion of the semiconductor layer. Then, a pair of a source electrode and a drain electrode composed of metallic materials was formed on the interlayer insulating layer such that they filled the contact holes. Thereafter, another interlayer insulating layer was formed to cover the interlayer insulating layer described above, and the pair of the source electrode and the drain electrode. TFT was thus formed. Finally, the glass substrate was irradiated with a laser (wavelength: 308 nm) from the side on which the resin film was not formed to separate the resin film and the glass substrate at the interface therebetween. The thus obtained TFT was subject to a TFT reliability test according to the method described in the section 6 above.

Thereafter, using the TFT before being separated from the glass substrate, a pixel electrode was patterned such that it was connected to the source electrode of the TFT. Then, a bank was formed in a shape that covers the periphery of the pixel electrode. Thereafter, a hole transport layer, an organic light emitting layer, and an electron transport layer were sequentially deposited on the pixel electrode through a desired patterning mask in a vacuum evaporator. Then, after a counter electrode was patterned, a sealing film was formed by a CVD method. Finally, the glass substrate was irradiated with a laser (wavelength: 308 nm) from the side on which the resin film was not formed for separation at the interface with the resin film.

In this manner, an organic EL display comprising the resin film as a substrate was obtained. The resulting organic EL display was applied with a voltage via a driving circuit and thereby made to emit light. Then, the ratio L₁/L₀ of the emission luminance immediately after the voltage application L₀ and the emission luminance after operating for 1 hour L₁ was determined. L₁/L₀ means that the closer the value is to 1, the longer the reliability of the organic EL display can be maintained.

### Examples 2 to 12 and Comparative Examples 1 to 8

In Examples 2 to 12 and Comparative Examples 1 to 8, evaluation was carried out in the same manner as in Example 1 except that the varnish used was changed to any of the varnishes of Synthesis Examples 1 to 15, and that the heating temperature for the coating film was changed to 350° C., 400° C., 450° C., or 500° C., as described in Tables 2, 3-1, and 3-2.

The evaluation results of Examples 1 to 12 and Comparative Examples 1 to 8 are shown in Tables 2, 3-1, and 3-2.

TABLE 2

| | | Example | | | | | | | | |
|---|---|---|---|---|---|---|---|---|---|---|
| | | Example 1 | Example 2 | Example 3 | Example 4 | Example 5 | Example 6 | Example 7 | Example 8 | Example 9 |
| | | Synthesis | Synthesis | Synthesis | Synthesis | Synthesis | Synthesis | Synthesis | Synthesis | Synthesis |
| Synthesis Example | | Example 1 | Example. 2 | Example 2 | Example 2 | Example 3 | Example 3 | Example 4 | Example 4 | Example 5 |
| Firing temperature | ° C. | 400 | 450 | 400 | 450 | 350 | 400 | 400 | 450 | 450 |
| Electric charge | cm⁻³ | 0.062 | 0.84 | 0.51 | 0.63 | 0.00042 | 0.0011 | 0.41 | 0.52 | 0.78 |
| change in | | | | | | | | | | |
| film (×10¹⁶) | | | | | | | | | | |
| Light transmittance | % | 67 | 67 | 85 | 77 | 92 | 91 | 93 | 89 | 68 |
| 0.05% weight loss | ° C. | 483 | 503 | 485 | 514 | 397 | 431 | 470 | 499 | 508 |
| temperature | | | | | | | | | | |
| CTE | ppm/° C. | 3 | 3 | 5 | 5 | 18 | 19 | 35 | 34 | 3 |
| Film lifting | Number | 5 | 0 | 4 | 0 | 21 | 15 | 6 | 0 | 0 |
| ΔVth | V | 0.3 | 0.4 | 0.2 | 0.2 | 0 | 0 | 0.2 | 0.2 | 0.3 |
| L₁/L₀ | — | 0.82 | 0.79 | 0.92 | 0.88 | 0.99 | 0.99 | 0.85 | 0.91 | 0.80 |

TABLE 3-1

| | | Example | | | | | |
|---|---|---|---|---|---|---|---|
| | | | | | Comparative | Comparative | Comparative |
| | | Example 10 | Example 11 | Example 12 | Example 1 | Example 2 | Example 3 |
| | | Synthesis | Synthesis | Synthesis | Synthesis | Synthesis | Synthesis |
| Synthesis Example | | Example 6 | Example 7 | Example 12 | Example 8 | Example 8 | Example 9 |
| Firing temperature | ° C. | 450 | 450 | 450 | 450 | 500 | 450 |
| Electric charge change in | cm⁻³ | 0.93 | 0.81 | 0.98 | 1.6 | 3.4 | 1.8 |
| film (×10¹⁶) | | | | | | | |
| Light transmittance | % | 60 | 60 | 61 | 59 | 49 | 50 |
| 0.05% weight loss | ° C. | 502 | 488 | 489 | 509 | 499 | 500 |
| temperature | | | | | | | |
| CTE | ppm/° C. | 3 | 3 | 3 | 3 | 3 | 3 |
| Film lifting | Number | 0 | 1 | 2 | 0 | 0 | 0 |
| ΔVth | V | 0.4 | 0.4 | 0.4 | 0.9 | 2.0 | 0.9 |
| L₁/L₀ | — | 0.71 | 0.70 | 0.78 | 0.42 | 0.33 | 0.51 |

TABLE 3-2

| | | Example | | | | |
|---|---|---|---|---|---|---|
| | | Comparative | Comparative | Comparative | Comparative | Comparative |
| | | Example 4 | Example 5 | Example 6 | Example 7 | Example 8 |
| | | Synthesis | Synthesis | Synthesis | Synthesis | Synthesis |
| Synthesis Example | | Example 6 | Example 7 | Example 12 | Example 8 | Example 8 |
| Firing temperature | ° C. | 450 | 450 | 450 | 450 | 450 |
| Electric charge change in | cm⁻³ | 1.9 | 1.1 | 1.4 | 1.2 | 1.9 |
| film (×10¹⁶) | | | | | | |
| Light transmittance | % | 58 | 73 | 73 | 72 | 57 |
| 0.05% weight loss | ° C. | 492 | 502 | 508 | 504 | 498 |
| temperature | | | | | | |
| CTE | ppm/° C. | 4 | 5 | 5 | 5 | 3 |
| Film lifting | Number | 0 | 0 | 0 | 0 | 0 |
| ΔVth | V | 0.8 | 0.6 | 0.7 | 0.6 | 0.9 |
| L₁/L₀ | — | 0.51 | 0.55 | 0.50 | 0.54 | 0.45 |

As described above, the resin film, the electronic device, the method of manufacturing the resin film, and the method of manufacturing the electronic device according to the present invention are suitable to realize a resin film that, when used as a substrate for a semiconductor element, can prevent changes in the properties of the semiconductor element during a long-term operation, and to improve the reliability of an electronic device by using the resin film as a substrate for a semiconductor element.

### REFERENCE SIGNS LIST

1 electronic device
10 resin film
20 element layer
21 semiconductor element
22 semiconductor layer
23 gate insulating layer
24 gate electrode
25 drain electrode
26 source electrode
27, 28 interlayer insulating layer
30 light emitting layer
31, 32, 33 image display element
34 pixel electrode
35 bank
36 counter electrode
37 sealing film

1. A resin film comprising polyimide, wherein the electric charge change in film, which is the amount of change in the electric charge in the resin film, after irradiation with a light having a wavelength of 470 nm and an intensity of 4.0 μW/cm² for 30 minutes, relative to before irradiation with the light, is 1.0×10¹⁶ cm⁻³ or less.

2. The resin film according to claim 1, wherein the 0.05% weight loss temperature is 490° C. or higher.

3. The resin film according to claim 1, wherein the light transmittance at a wavelength of 470 nm when the thickness of the resin film is set to 10 μm is 60% or more.

4. The resin film according to claim 1, wherein 50 mol % or more of the 100 mol % of tetracarboxylic acid residues contained in the polyimide is composed of at least one selected from a pyromellitic acid residue and a biphenyltetracarboxylic acid residue; and
wherein 50 mol % or more of the diamine residues contained in the 100 mol % of polyimide is composed of a p-phenylenediamine residue.

5. The resin film according to claim 1, wherein the value obtained by dividing the number of moles of the tetracarboxylic acid residues contained in the polyimide by the number of moles of the diamine residues contained in the polyimide is from 1.001 to 1.100.

6. The resin film according to claim 1, wherein the polyimide comprises at least one of the structure represented by Chemical Formula (1) and the structure represented by Chemical Formula (2): 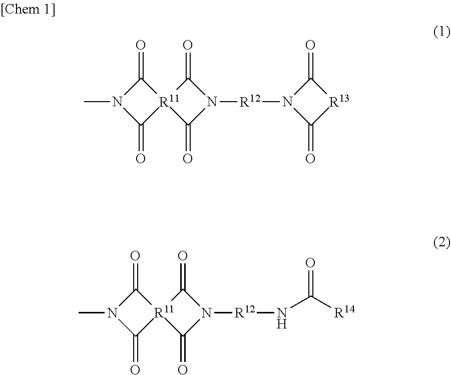
wherein, in Chemical Formula (1), R¹¹ represents a tetravalent tetracarboxylic acid residue having two or more carbon atoms;
R¹² represents a divalent diamine residue having two or more carbon atoms; and
R¹³ represents a divalent dicarboxylic acid residue having two or more carbon atoms;
and wherein, in Chemical Formula (2), R¹¹ represents a tetravalent tetracarboxylic acid residue having two or more carbon atoms;
R¹² represents a divalent diamine residue having two or more carbon atoms; and
R¹⁴ represents a monovalent carboxylic acid residue having one or more carbon atoms.

7. An electronic device, comprising:
a resin film according to claim 1; and
a semiconductor element formed on the resin film.

8. The electronic device according to claim 7, wherein the semiconductor element is a thin-film transistor.

9. The electronic device according to claim 7, further comprising an image display element.

10. A method of producing a resin film according to claim 1, comprising:
an application step for applying a resin composition comprising a polyimide precursor and a solvent to a support; and
a heating step for heating the coating film obtained by the application step to obtain a resin film.

11. The method of producing a resin film according to claim 10, wherein the heating temperature for the coating film in the heating step is from 420° C. to 490° C.

12. The method of producing a resin film according to claim 10, wherein the polyimide precursor has the structure represented by Chemical Formula (3): 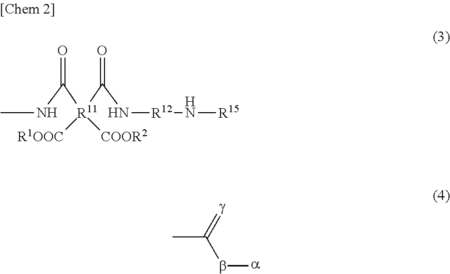
wherein, in Chemical Formula (3), R¹¹ represents a tetravalent tetracarboxylic acid residue having two or more carbon atoms;
R¹² represents a divalent diamine residue having two or more carbon atoms;
R¹⁵ represents the structure represented by Chemical Formula (4); and
R¹ and R² each independently represent a hydrogen atom, a hydrocarbon group having 1 to 10 carbon atoms, an alkylsilyl group having 1 to 10 carbon atoms, an alkali metal ion, an ammonium ion, an imidazolium ion, or a pyridinium ion;
and wherein, in Chemical Formula (4), α represents a monovalent hydrocarbon group having two or more carbon atoms; and
β and γ each independently represent an oxygen atom or a sulfur atom.

13. The method of producing a resin film according to claim 10, wherein the polyimide precursor has the structure represented by Chemical Formula (5): 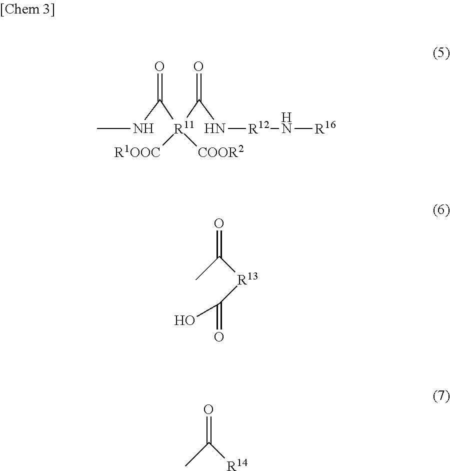
wherein, in Chemical Formula (5), R¹¹ represents a tetravalent tetracarboxylic acid residue having two or more carbon atoms;
R¹² represents a divalent diamine residue having two or more carbon atoms; and
R¹⁶ represents the structure represented by Chemical Formula (6) or the structure represented by Chemical Formula (7);
and wherein, in Chemical Formula (6), R¹³ represents a divalent dicarboxylic acid residue having two or more carbon atoms;
and wherein, in Chemical Formula (7), R¹⁴ represents a monovalent monocarboxylic acid residue having one or more carbon atoms.

14. The method of producing a resin film according to claim 10, wherein the resin composition comprises at least one of a compound having the structure represented by Chemical Formula (8) and a compound having the structure represented by Chemical Formula (9) in an amount ranging from 0.05 parts by mass to 5.0 parts by mass based on 100 parts by mass of the polyimide precursor; 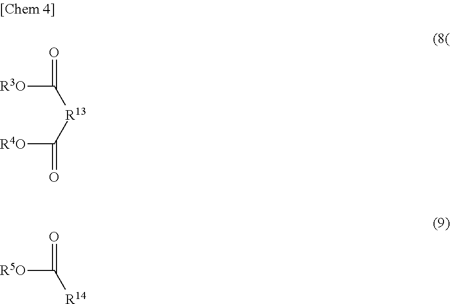
wherein, in Chemical Formula (8), R¹³ represents a divalent dicarboxylic acid residue having two or more carbon atoms; and
R³ and R⁴ each independently represent a hydrogen atom, a hydrocarbon group having 1 to 10 carbon atoms, an alkylsilyl group having 1 to 10 carbon atoms, an alkali metal ion, an ammonium ion, an imidazolium ion, or a pyridinium ion;
and wherein, in Chemical Formula (9), R¹⁴ represents a monovalent monocarboxylic acid residue having one or more carbon atoms; and
R⁵ represents a hydrogen atom, a hydrocarbon group having 1 to 10 carbon atoms, an alkylsilyl group having 1 to 10 carbon atoms, an alkali metal ion, an ammonium ion, an imidazolium ion, or a pyridinium ion.

15. A method of manufacturing an electronic device, comprising:
a film production step for producing a resin film on a support by the method of producing a resin film according to claim 10;
an element formation step for forming a semiconductor element on the resin film; and
a separation step for separating the resin film from the support.

16. The method of manufacturing an electronic device according to claim 15, wherein the semiconductor element is a thin-film transistor.
